(19) United States
(12) Patent Application Publication
(10) Pub. No.: US 2026/0190719 A1
(43) Pub. Date: Jul. 2, 2026

(54) DISPLAY PANEL

(71) Applicants: Chengdu BOE Optoelectronics Technology, Co., Ltd., Chengdu, Sichuan (CN); BOE Technology Group Co., Ltd., Beijing (CN)

(72) Inventors: Yuanjie Xu, Beijing (CN); Taofeng Xie, Beijing (CN); Xing Yao, Beijing (CN)

(73) Assignees: Chengdu BOE Optoelectronics Technology, Co., Ltd., Chengdu, Sichuan (CN); BOE Technology Group Co., Ltd., Beijing (CN)

(21) Appl. No.: 18/848,795

(22) PCT Filed: Oct. 31, 2023
(86) PCT No.: PCT/CN2023/128489

§ 371 Date: Sep. 19, 2024

(51) Int. Cl. H10K 59/131; H10K 59/126; H10K 59/88

(52) U.S. Cl. CPC H10K 59/1315; H10K 59/126; H10K 59/88

(57) ABSTRACT

A display panel and a display device. The display panel includes a common power supply wire and a metal mesh structure located in the peripheral region. The metal mesh structure is connected with the common power supply wire which includes a first wire segment with a first wire width and a second wire segment with a second wire width different from the first wire width, the first wire segment and the second wire segment are directly connected. The metal mesh structure includes a functional mesh portion and a main mesh portion, the functional mesh portion is closer to a connection position of the first wire segment and the second wire segment than the main mesh portion, and a resistance in unit area of the functional mesh portion is smaller than a resistance in unit area of the main mesh portion.

### TECHNICAL FIELD

Embodiments of the present disclosure relate to a display panel and a display device.

### BACKGROUND

The organic light-emitting diode (OLED) display device has a series of advantages, such as self-luminescence, high contrast, high definition, wide viewing angle, low power consumption, fast response and low manufacturing cost, etc. It has become one of the key development directions of the new generation of display devices, so it has attracted more and more attention.

### SUMMARY

Embodiments of the present disclosure provide a display panel and a display device, by making a resistance in a unit area of a functional mesh portion smaller than a resistance in the unit area of a main mesh portion, the current at a connection position can be dispersed, the current density at the connection position is reduced, and the problem of local region heating is solved.

At least one embodiment of the present disclosure provides a display panel, including a display region and a peripheral region around the display region, wherein the display panel includes a common power supply wire in the peripheral region and a metal mesh structure in the peripheral region, the metal mesh structure is located at a side of the common power supply wire close to the display region, the metal mesh structure is connected to the common power supply wire, and a part of wires of the metal mesh structure extends to the display region, the common power supply wire includes a first wire segment with a first wire width and a second wire segment with a second wire width, the first wire width is different from the second wire width, and the first wire segment is directly connected to the second wire segment, the metal mesh structure includes a functional mesh portion and a main mesh portion, the functional mesh portion is closer to a connection position of the first wire segment and the second wire segment than the main mesh portion, and a resistance per unit area of the functional mesh portion is smaller than a resistance per unit area of the main mesh portion.

For example, in the display panel provided by an embodiment of the present disclosure, an extending direction of the first wire segment is different from an extending direction of the second wire segment.

For example, in the display panel provided by an embodiment of the present disclosure, the first wire segment includes an arc segment, the arc segment is directly connected to the second wire segment.

For example, in the display panel provided by an embodiment of the present disclosure, the main mesh portion includes a first mesh portion and a second mesh portion, the first mesh portion and the second mesh portion are located at two sides of the functional mesh portion, the first mesh portion is connected with the first wire segment, the second mesh portion is connected with the second wire segment, and the functional mesh portion is connected with both the first wire segment and the second wire segment.

For example, in the display panel provided by an embodiment of the present disclosure, mesh wires in the first mesh portion are all connected to the first wire segment, and mesh wires in the second mesh portion are all connected to the second wire segment.

For example, in the display panel provided by an embodiment of the present disclosure, a ratio of the first wire width to the second wire width is greater than or equal to 2.

For example, in the display panel provided by an embodiment of the present disclosure, the peripheral region includes a bonding region, wherein the second wire width is less than the first wire width, and the second wire segment is located at a side of the display region close to the bonding region.

For example, in the display panel provided by an embodiment of the present disclosure, the functional mesh portion and the main mesh portion are arranged in a same layer, and a number of mesh wires per unit area of the functional mesh portion is greater than a number of mesh wires per unit area of the main mesh portion.

For example, in the display panel provided by an embodiment of the present disclosure, the functional mesh portion and the main mesh portion are arranged in a same layer, and a wire width of each of the mesh wires of the functional mesh portion is greater than a wire width of each of the mesh wires of the main mesh portion.

For example, in the display panel provided by an embodiment of the present disclosure, the functional mesh portion and the main mesh portion are arranged in a same layer, and a number of mesh wires per unit area of the functional mesh portion decreases in a direction of the functional mesh portion towards the main mesh portion.

For example, in the display panel provided by an embodiment of the present disclosure, the functional mesh portion and the main mesh portion are arranged in a same layer, the main mesh portion includes a first mesh pattern, the functional mesh portion includes a second mesh pattern, the second mesh pattern includes the first mesh pattern and a plurality of straight wire segments, and the plurality of straight wire segments extend from a side of the functional mesh portion close to the display region to the common power supply wire in a divergent manner.

For example, in the display panel provided by an embodiment of the present disclosure, the functional mesh portion includes a first mesh layer and a second mesh layer electrically connected to each other, the first mesh layer and the main mesh portion are arranged in a same layer, and the first mesh layer and the second mesh layer are arranged in different layers.

For example, in the display panel provided by an embodiment of the present disclosure, in a direction perpendicular to the display panel, the first mesh layer includes an approximately same mesh pattern as the second mesh layer.

For example, the display panel provided by an embodiment of the present disclosure further includes: a base substrate and a pixel circuit driver layer formed on the base substrate, wherein the pixel circuit driver layer includes a plurality of conductive patterns arranged sequentially in a direction perpendicular to the base substrate, and the plurality of conductive patterns include a first conductive pattern and a second conductive pattern, the first mesh layer and the main mesh portion are located in a same conductive layer as the first conductive pattern, and the second mesh layer is located in a same conductive layer as the second conductive pattern.

For example, in the display panel provided by an embodiment of the present disclosure, the first mesh layer is located at a side of the second mesh layer away from the base substrate, in the direction perpendicular to the base substrate, an orthographic projection of each of mesh wires of the first mesh layer on the base substrate falls into an orthographic projection of each of mesh wires of the second mesh layer on the base substrate.

For example, the display panel provided by an embodiment of the present disclosure further includes: a base substrate, a pixel circuit driver layer formed on the base substrate and a shielding metal layer located between the base substrate and the pixel circuit driver layer, wherein the pixel circuit driver layer includes a plurality of conductive patterns arranged sequentially in a direction perpendicular to the base substrate, and the plurality of conductive patterns include a first conductive pattern, the first mesh layer and the main mesh portion are located in a same conductive layer as the first conductive pattern, and the second mesh layer is located in a same conductive layer as the shielding metal layer.

For example, in the display panel provided by an embodiment of the present disclosure, the functional mesh portion further includes a third mesh layer located between the first mesh layer and the second mesh layer, the plurality of conductive patterns further include a second conductive pattern, and the third mesh layer is located in a same conductive layer as the second conductive pattern.

For example, the display panel provided by an embodiment of the present disclosure further includes: a base substrate, a pixel circuit driver layer formed on the base substrate, and a first electrode layer formed on a side of the pixel circuit driver layer away from the base substrate, wherein the pixel circuit driver layer includes a plurality of conductive patterns arranged sequentially in a direction perpendicular to the base substrate, and the plurality of conductive patterns include a first conductive pattern, the first mesh layer and the main mesh portion are located in a same conductive layer as the first conductive pattern, and the second mesh layer is located in a same conductive layer as the first electrode layer.

For example, the display panel provided by an embodiment of the present disclosure further includes: a base substrate, wherein the metal mesh structure is located on the base substrate; a plurality of insulation layers, located at a side of the metal mesh structure away from the base substrate, wherein, along a direction perpendicular to the base substrate, a thickness of a region of the plurality of insulating layers overlapping with the functional mesh portion is smaller than a thickness of other region of the plurality of insulating layers.

For example, the display panel provided by an embodiment of the present disclosure further includes: first transfer wires, extending in a first direction; second transfer wires, extending in a second direction and arranged in a different layer as the first transfer wires; first dummy wires, extending in the first direction; second dummy wires, extending in the second direction and arranged in a different layer as the first dummy wires; data wires, extending in the second direction, wherein an end of each of the first transfer wires is connected with one of the data wires through one of first via holes, another end of each of the first transfer wires is connected with one of the second transfer wires through one of second via holes, the first via holes and the second via holes form a first transfer region, the peripheral region includes a bonding region, and the first transfer region is located at a side of the display region close to the bonding region, the display panel further includes a light-emitting component, the first dummy wires and the second dummy wires are connected with a cathode of the light-emitting component and are configured to transmit a power supply voltage, the first dummy wires and the second dummy wires are connected through third via holes, and the third via holes form a plurality of second transfer regions.

For example, in the display panel provided by an embodiment of the present disclosure, the part of the wires of the metal mesh structure extending into the display region includes a part of the first dummy wires, or the part of the wires of the metal mesh structure extending into the display region includes a part of the second dummy wires.

For example, the display panel provided by an embodiment of the present disclosure further includes: a base substrate and a pixel circuit driver layer formed on the base substrate, wherein the pixel circuit driver layer includes a plurality of conductive patterns arranged sequentially in a direction perpendicular to the base substrate, and the plurality of conductive patterns include a first conductive pattern and a second conductive pattern, the first transfer wires and the first dummy wires are located in a same conductive layer as the first conductive pattern, and the second transfer wires and the second dummy wires are located in a same conductive layer as the second conductive pattern.

For example, the display panel provided by an embodiment of the present disclosure further includes: third transfer wires, extending in the first direction; fourth transfer wires, extending in the second direction and arranged in a different layer as the third transfer wires; third dummy wire, extending in the first direction; fourth dummy wire, extending in the second direction and arranged in a different layer as the third dummy wires; data wires, extending in the second direction, wherein an end of each of the third transfer wires is connected with one of the data wires through one of fourth via holes, another end of each of the third transfer wires is connected with one of the fourth transfer wires through one of fifth via holes, the fourth via holes and the fifth via holes form a plurality of third transfer regions, the plurality of third transfer regions are spaced with each other in the first direction, the display panel includes a display region and a peripheral region surrounding the display region, the peripheral region includes a bonding region, and the plurality of third transfer regions are located at a side of the display region close to the bonding region, the display panel further includes a light-emitting component, the third dummy wires and the fourth dummy wires are connected with a cathode of the light-emitting component and are configured to transmit a power supply voltage, the third dummy wires and the fourth dummy wires are connected through sixth via holes, and the sixth via holes form a plurality of fourth transfer regions, along the first direction, at least one of the plurality of fourth transfer regions is located among the plurality of third transfer regions.

For example, the display panel provided by an embodiment of the present disclosure further includes: a lead wire, located between the display region and the bonding region, wherein the bonding region includes a common power supply terminal, the common power supply terminal is configured to transmit a common power supply signal and an end of the lead wire is connected to the common power supply terminal, the plurality of fourth transfer regions include a first sub-region, and along the first direction, the first sub-region is located among the plurality of third transfer regions, and a part of the fourth dummy wires in the first sub-region is connected with another end of the lead wire.

For example, the display panel provided by an embodiment of the present disclosure further includes: a base substrate; a pixel circuit driver layer, located on the base substrate; and a common power supply mesh layer, located at a side of the pixel circuit driver layer away from the base substrate, wherein the pixel circuit driver layer includes a plurality of conductive patterns arranged sequentially in a direction perpendicular to the base substrate, and the metal mesh structure and the common power supply wire are located in a same conductive layer as the plurality of conductive patterns, the common power supply mesh layer includes mesh wires located in the display region and a peripheral common power supply wire located in the peripheral region, the peripheral region includes a bonding region, the display panel further includes a lead wire, the lead wire is located between the display region and the bonding region, the bonding region includes a common power supply terminal, the common power supply terminal is configured to transmit a common power supply signal, an end of the lead wire is connected to the common power supply terminal and another end of the lead wire is connected to the mesh wires of the common power mesh layer.

For example, the display panel provided by an embodiment of the present disclosure further includes: a light-emitting device layer, located at a side of the common power supply mesh layer away from the base substrate.

For example, the display panel provided by an embodiment of the present disclosure further includes: a plurality of pixels, wherein each of the plurality of pixels includes an effective light-emitting region and a non-display region surrounding the effective light-emitting region, wherein an orthographic projection of the mesh wires of the common power supply mesh layer on the base substrate is in an orthographic projection of the non-display region on the base substrate.

At least one embodiment of the present disclosure further provides a display panel, which includes: third transfer wires, extending in a first direction; fourth transfer wire, extending in a second direction and arranged in a different layer as the third transfer wires; third dummy wires, extending in the first direction; fourth dummy wire, extending in the second direction and arranged in a different layer as the third dummy wires; data wires, extending in the second direction, wherein an end of each of the third transfer wires is connected with one of the data wires through one of fourth via holes, another end of each of the third transfer wires is connected with one of the fourth transfer wires through one of fifth via holes, the fourth via holes and the fifth via holes form a plurality of third transfer regions, the plurality of third transfer regions are spaced with each other in the first direction, the display panel includes a display region and a peripheral region surrounding the display region, the peripheral region includes a bonding region, and the plurality of third transfer regions are located at a side of the display region close to the bonding region, the display panel further includes a light-emitting component, the third dummy wires and the fourth dummy wires are connected with a cathode of the light-emitting component and are configured to transmit a power supply voltage, the third dummy wires and the fourth dummy wires are connected through sixth via holes, and the sixth via holes form a plurality of fourth transfer regions, along the first direction, at least one of the plurality of fourth transfer region is located among the plurality of third transfer regions.

For example, the display panel provided by an embodiment of the present disclosure further includes: a lead wire, located between the display region and the bonding region, wherein the bonding region includes a common power supply terminal, the common power supply terminal is configured to transmit a common power supply signal and an end of the lead wire is connected to the common power supply terminal, the plurality of fourth transfer regions include a first sub-region, and along the first direction, the first sub-region is located among the plurality of third transfer regions, and a part of the fourth dummy wires of the first sub-region is connected with another end of the lead wire.

For example, the display panel provided by an embodiment of the present disclosure further includes: the third transfer wires are arranged in a same layer as the third dummy wires.

For example, in the display panel provided by an embodiment of the present disclosure, the fourth transfer wires are arranged in a same layer as the fourth dummy wires.

For example, the display panel provided by an embodiment of the present disclosure further includes: a base substrate and a pixel circuit driver layer formed on the base substrate, wherein the pixel circuit driver layer includes a plurality of conductive patterns arranged sequentially in a direction perpendicular to the base substrate, and the plurality of conductive patterns include a first conductive pattern and a second conductive pattern, the third transfer wire and the third dummy wire are located in a same layer as the first conductive pattern, and the fourth transfer wire and the fourth dummy wire are located in a same layer as the second conductive pattern.

At least one embodiment of the present disclosure further provides a display panel, which includes: a base substrate; a pixel circuit driver layer, located on the base substrate; and a common power supply mesh layer located at a side of the pixel circuit driver layer away from the base substrate, wherein the display panel includes a display region and a peripheral region surrounding the display region, and the common power supply mesh layer includes mesh wires located in the display region and a peripheral common power supply wire located in the peripheral region, the peripheral region includes a bonding region, the display panel further includes a lead wire located between the display region and the bonding region, the bonding region includes a common power supply terminal, the common power supply terminal is configured to transmit a common power supply signal, an end of the lead wire is connected to the common power supply terminal and another end of the lead wire is connected to the mesh wires of the common power mesh layer.

For example, in the display panel provided by an embodiment of the present disclosure, wherein the peripheral common power supply wire includes a third wire segment with a third wire width and a fourth wire segment with a fourth wire width, the third wire width is different from the fourth wire width, and the third wire segment is directly connected to the fourth wire segment.

For example, the display panel provided by an embodiment of the present disclosure further includes: a light-emitting device layer, located at a side of the common power supply mesh layer away from the base substrate.

For example, the display panel provided by an embodiment of the present disclosure further includes: a plurality of pixels, wherein each of the plurality of pixels includes an effective light-emitting region and a non-display region surrounding the effective light-emitting region, wherein orthographic projections of the mesh wires of the common power supply mesh layer on the base substrate is in an orthographic projection of the non-display region on the base substrate.

For example, the display panel provided by an embodiment of the present disclosure further includes: a common power supply wire, located in the peripheral region; and a metal mesh structure, located in the peripheral region and on a side of the common power supply wire close to the display region, wherein the metal mesh structure is connected with the common power supply wire, and a part of wires of the metal mesh structure extends to the display region, the pixel circuit driver layer includes a plurality of conductive patterns arranged sequentially in a direction perpendicular to the base substrate, and the plurality of conductive patterns include a first conductive pattern, the common power supply wire and the metal mesh structure are located in a same conductive layer as the first conductive pattern.

At least one embodiment of the present disclosure further provides a display device, including any of the display panel described above.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a wiring diagram of a partial position of a border of a display panel;

FIG. 2 is a schematic sectional view of FIG. 1;

FIG. 3 is a simulation diagram of current density illustrated by FIG. 1;

FIG. 4 is a schematic plan diagram of a display panel according to an embodiment of the present disclosure;

FIG. 5 is a partial wiring diagram of a display panel illustrated by FIG. 4;

FIG. 6 is a partial enlarged view of FIG. 5;

FIG. 7 is a schematic sectional view of FIG. 6;

FIG. 8 is a partially enlarged wiring diagram of a display panel according to an embodiment of the present disclosure;

FIG. 9 is a schematic sectional view of FIG. 8;

FIG. 10 is a partially enlarged wiring diagram of a metal mesh structure of a display panel according to an embodiment of the present disclosure;

FIG. 11 is a partially enlarged wiring diagram of a display panel according to an embodiment of the present disclosure;

FIG. 12 is a schematic sectional view of FIG. 11;

FIG. 13 is a partial enlarged view of a first mesh layer of a display panel according to an embodiment of the present disclosure;

FIG. 14 is a partial enlarged view of a second mesh layer of a display panel illustrated by FIG. 13;

FIG. 15 is a partial sectional view of a display panel illustrated by FIG. 13;

FIG. 16 is a partial enlarged diagram of another second conductive layer of the display panel illustrated by FIG. 13;

FIG. 17 is a partial sectional view of a display panel illustrated by FIG. 13;

FIG. 18 is a partial wiring diagram of a display panel illustrated by FIG. 13;

FIG. 19 is a partial sectional view of a display panel illustrated by FIG. 18;

FIG. 20 is a partial wiring diagram of a display panel according to an embodiment of the present disclosure;

FIG. 21 is a partial wiring diagram of a second mesh layer of a display panel illustrated by FIG. 20;

FIG. 22 is a partial sectional view of a display panel illustrated by FIG. 20;

FIG. 23 is a partial wiring diagram of a display panel according to an embodiment of the present disclosure;

FIG. 24 is a partial sectional view of FIG. 23;

FIG. 25 is a schematic diagram of a display panel according to an embodiment of the present disclosure;

FIG. 26 is a partial schematic enlarged view of FIG. 25;

FIG. 27 is another schematic diagram of a display panel according to an embodiment of the present disclosure;

FIG. 28 is a partial schematic enlarged view of FIG. 27;

FIG. 29 is a schematic plan view of a common power mesh layer of a display panel according to an embodiment of the present disclosure;

FIG. 30 is a partial schematic diagram of a common power mesh layer illustrated by FIG. 29;

FIG. 31 is a schematic sectional view of FIG. 29;

FIG. 32 is another schematic sectional view of a display panel illustrated by

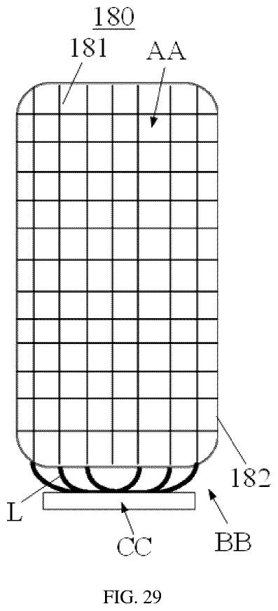

FIG. 29;

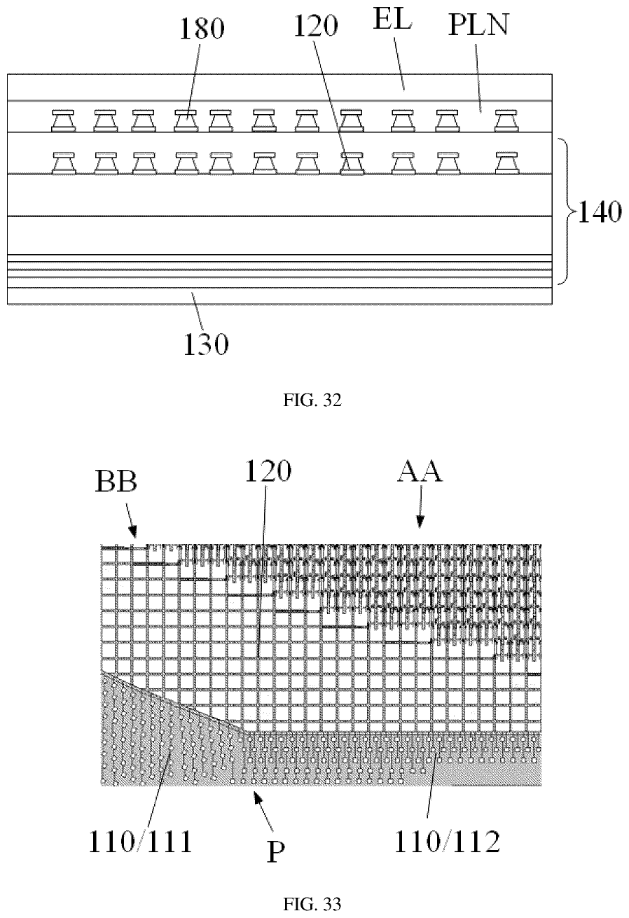

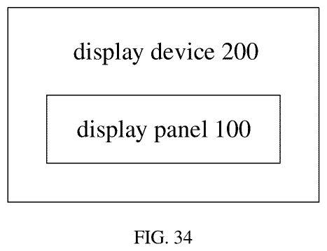

FIG. 33 is a schematic plan view of a metal mesh structure of FIG. 32; and

FIG. 34 is a schematic diagram of a display device according to an embodiment of the present disclosure.

### DETAILED DESCRIPTION

In order to make objectives, technical details, and advantages of the embodiments of the present disclosure more clear, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “include,” “including,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Unless otherwise defined, the features of “parallel”, “vertical” and “identical” used in the embodiments of the present disclosure include the strict sense of “parallel”, “vertical” and “identical”, as well as the situations involving certain errors such as “substantially parallel”, “substantially vertical” and “substantially identical”. For example, the above-mentioned “substantially” can indicate that the difference value of the compared object is within 10% or 5% of the average value of the compared object. When the number of a component or element is not specifically indicated in the following embodiments of the present disclosure, it means that the component or element can be one or more, or can be understood as at least one. “At least one” refers to one or more, and “more than one” refers to at least two. The “arranged in the same layer” in the embodiments of the present disclosure refers to the relationship between multiple film layers formed by the same material after the same step (e.g., a one-step patterning process). Here, “in the same layer” does not always refer to the thickness of multiple film layers being the same or the height of multiple film layers being the same in the cross-sectional view.

The high brightness mode (HBM) is a display mode of a display panel. In strong light, such as outdoor strong light environment, the contrast of low brightness is not enough, so HBM mode display is needed to maintain sufficient contrast, and fingerprint or face recognition under strong light is easily affected by external light, which affects the corresponding speed and signal-to-noise ratio. Improving brightness of HBM can improve fingerprint or face recognition performance under strong light, so the brightness requirement of HBM is getting higher and higher. For example, the requirements for HBM brightness of some products have already exceed 2000 nits. However, the higher the brightness requirement, the higher the corresponding current requirement. When the wire of a common voltage source supply (VSS) passes through a narrow corner of a border of a display panel, a narrow position at the corner is likely to lead to excessive current density which leads to the display panel becoming hot, resulting in a decrease in luminous efficiency and even wire burns. Although the display panel can emit relatively high brightness at the same current by improving the luminous efficiency of the light-emitting component, it is still difficult to meet the brightness requirements by improving the luminous efficiency of the light-emitting components alone.

With the increasing demand for narrow border of display panel, for example, the distance from the display region to the lower border of some products is getting smaller and smaller, reaching 500 μm, which leads to the compression of signal wire space, and the current density of narrow border increases with the same current, which also bring the problem that the display panel is hot.

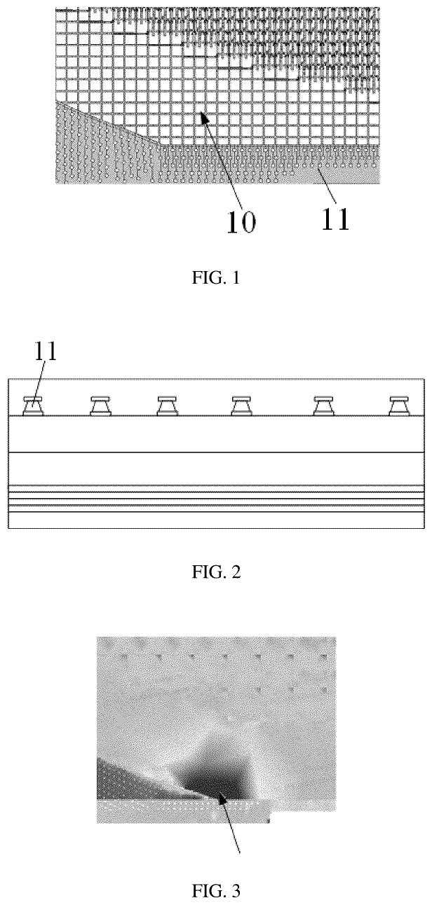

FIG. 1 is a wiring diagram of a partial position of a border of a display panel, FIG. 2 is a schematic sectional view of FIG. 1, and FIG. 3 is a current density simulation diagram of a display panel illustrated by FIG. 1. As illustrated by FIG. 1 and FIG. 2, at the corner of the border of the display panel, a metal mesh 10 is connected with a common power supply wire 11 to disperse the current of the common power supply wire 11 and reduce the current density. However, as illustrated by FIG. 3, the current density is the highest, reaching 1.56*109 A/m², at a position where the width and direction of the common power supply wire 11 changes (the position indicated by the arrow in the figure), which bring the problem that the display panel is hot and result in the problem of decreased luminous efficiency and even wire burns.

In this regards, embodiments of the present disclosure provide a display panel and a display device. The display panel includes a display region and a peripheral region surrounding the display region, and the display panel includes a common power supply wire in the peripheral region and a metal mesh structure in the peripheral region, the metal mesh structure is located at a side of the common power supply wire close to the display region, the metal mesh structure is connected to the common power supply wire, and a part of wires of the metal mesh structure extends to the display region. The common power supply wire includes a first wire segment with a first wire width and a second wire segment with a second wire width, the first wire width is different from the second wire width, and the first wire segment is directly connected to the second wire segment. The metal mesh structure includes a functional mesh portion and a main mesh portion, the functional mesh portion is closer to a connection position of the first wire segment and the second wire segment than the main mesh portion. A resistance per unit area of the functional mesh portion is smaller than a resistance per unit area of the main mesh portion.

In the display panel provided in the embodiments of the present disclosure, connecting the metal mesh structure with the common power supply wire may disperse the current and reduce the current density. At the connection position of the first wire segment and the second wire segment of the common power supply wire, the wire width of the common power supply wire changes due to the difference in the wire widths of the first wire segment and the second wire segment, and the current density at the connection position of the first wire segment and the second wire segment of the common power supply wire is greater than that at the other positions. By making the resistance per unit area of the functional mesh portion smaller than the resistance per unit area of the main mesh portion, the current at the connection position can be dispersed and the current density at the connection position can be reduced, and the current at the position with the maximum current density can be accurately and effectively reduced, thus solving the problem of local region heating. In addition, by making the resistance per unit area of the functional mesh portion smaller than the resistance per unit area of the main mesh portion, the structure of a heating position is improved and optimized in a targeted manner, which better solves the problem of local region heating without changing the structural design of other regions.

Hereinafter, the display panel and the display device provided by the embodiments of the present disclosure will be described in detail with reference to the accompanying drawings.

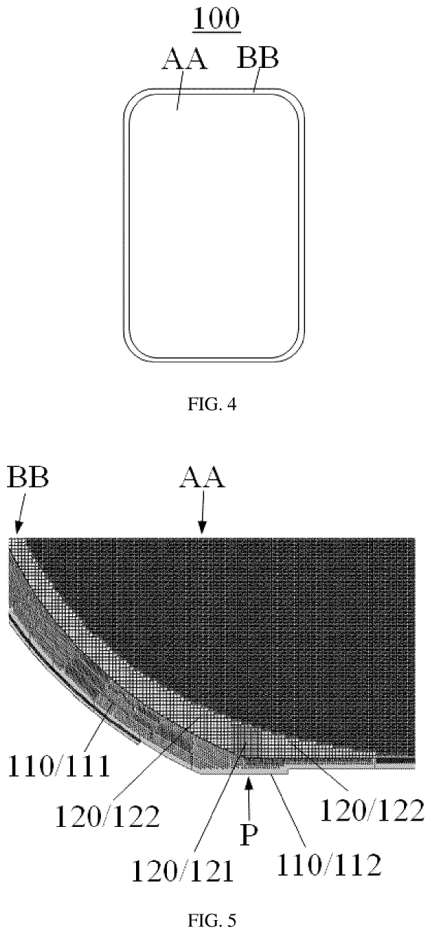

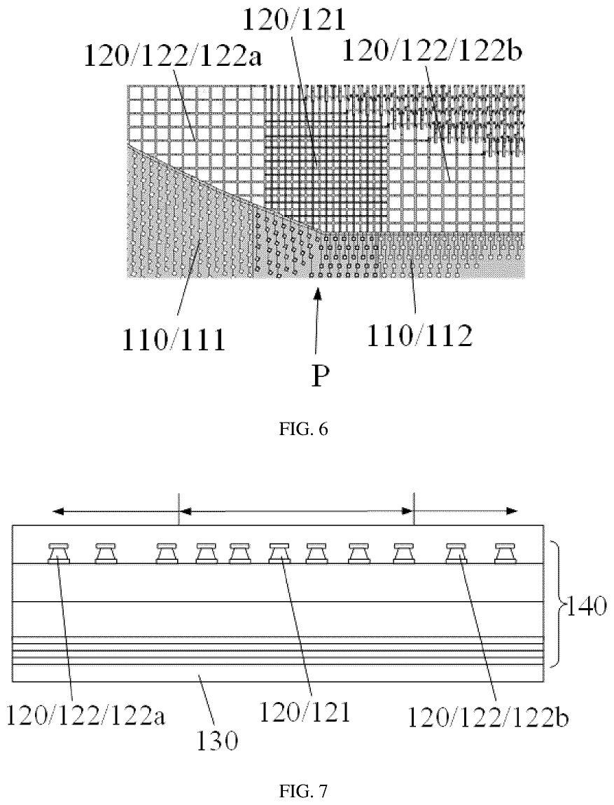

The embodiments of the present disclosure provide a display panel. FIG. 4 is a schematic plan diagram of a display panel according to an embodiment of the present disclosure, FIG. 5 is a partial wiring diagram of a display panel illustrated by FIG. 4; FIG. 6 is a partial enlarged view of FIG. 5; and FIG. 7 is a schematic sectional view of FIG. 6. As illustrated by FIG. 4 to FIG. 7, the display panel 100 includes a display region AA and a peripheral region BB around the display region AA, and the display panel 100 includes a common power supply wire 110 in the peripheral region BB and a metal mesh structure 120 in the peripheral region BB, the metal mesh structure 120 is located at a side of the common power supply wire 110 close to the display region AA, the metal mesh structure 120 is connected to the common power supply wire 110, and a part of wires of the metal mesh structure 120 extends to the display region AA. The common power supply wire 110 includes a first wire segment 111 with a first wire width and a second wire segment 112 with a second wire width, the first wire width is different from the second wire width, and the first wire segment 111 is directly connected to the second wire segment 112. The metal mesh structure 120 includes a functional mesh portion 121 and a main mesh portion 122, the functional mesh portion 121 is closer to a connection position P of the first wire segment 111 and the second wire segment 112 than the main mesh portion 122. A resistance per unit area of the functional mesh portion 121 is smaller than a resistance per unit area of the main mesh portion 122.

In the display panel 100 provided in the embodiment of the present disclosure, connecting the metal mesh structure 120 with the common power supply wire 110 may disperse the current and reduce the current density. At the connection position P of the first wire segment 111 and the second wire segment 112 of the common power supply wire 110, the wire width of the common power supply wire 110 changes due to the difference in the wire widths of the first wire segment 111 and the second wire segment 112, and the current density at the connection position P of the first wire segment 111 and the second wire segment 112 is greater than the current density at the other positions. By making the resistance per unit area of the functional mesh portion 121 smaller than the resistance per unit area of the main mesh portion 122, the current at the connection position P can be dispersed and the current density at the connection position P can be reduced, and the current at the position with the maximum current density can be accurately and effectively reduced, thus solving the problem of local region heating. In addition, by making the resistance per unit area of the functional mesh portion 121 smaller than the resistance per unit area of the main mesh portion 122, the structure of a heating position is improved and optimized in a targeted manner, which better solves the problem of local region heating without changing the structural design of other regions. For example, the common power supply wire 110 is used to transmit a first common power supply voltage (VSS).

In some examples, as illustrated by FIG. 5 and FIG. 6, the second wire width of the second wire segment 112 is smaller than the first wire width of the first wire segment 111. As the wire width becomes relatively small, the current density at the connection position P between the second wire segment 112 and the first wire segment 111 is too high, and local region is prone to heat. By optimizing the metal mesh structure 120 in this region, the current at the position with the maximum current density can be accurately and effectively reduced, and the problem of local region heating can be solved.

In some examples, as illustrated by FIG. 5 and FIG. 6, an extending direction of the first wire segment 111 is different from an extending direction of the second wire segment 112. For example, the extending direction of the first wire segment 111 and the extending direction of the second wire segment 112 have an included angle. For example, as illustrated by FIG. 4, the connection position P of the first wire segment 111 and the second wire segment 112 is located in a corner region of the display panel 100. For example, as illustrated by FIG. 4, the first wire segment 111 and the second wire segment 112 are located in an intersection region of two adjacent sides of the display panel 100.

In some examples, as illustrated by FIG. 5 and FIG. 6, the first wire segment 111 includes an arc segment, the arc segment is directly connected with the second wire segment 112. For example, the arc segment is located in the corner region of the display panel 100. For example, the arc segment is located in the intersection region of two adjacent sides of the display panel 100.

In some examples, as illustrated by FIG. 5 to FIG. 7, the main mesh portion 122 includes a first mesh portion 122a and a second mesh portion 122b, the first mesh portion 122a and the second mesh portion 122b are located at two sides of the functional mesh portion 121, the first mesh portion 122a is connected with the first wire segment 111, the second mesh portion 122b is connected with the second wire segment 112, and the functional mesh portion 121 is connected with both the first wire segment 111 and the second wire segment 112.

In some examples, as illustrated by FIG. 5 and FIG. 6, mesh wires in the first mesh portion 122a are all connected to the first wire segment 111, and mesh wires in the second mesh portion 122b are all connected to the second wire segment.

In some examples, as illustrated by FIG. 5, a ratio of the first wire width to the second wire width is greater than or equal to 2. By reducing the second wire width of the second wire segment 112, the border on a side where the second wire segment 112 is located can be narrowed, thus achieving a narrow border. The embodiments of the present disclosure do not limit the ratio of the first wire width to the second wire width, which may be designed according to the requirements of the display panel 100. For example, the ratio may also be greater than or equal to 2.5, and the ratio may be greater than or equal to 3.

For example, the peripheral region BB includes a bonding region, and the second wire segment 112 is located at a side of the display region AA close to the bonding region. By reducing the second wire width of the second wire segment 112, the border on a side of the display region AA close to the bonding region becomes relatively narrow. For example, as illustrated by FIG. 4, the border on a side where the second wire segment is located may be the lower border of the display panel 100.

In some examples, as illustrated by FIG. 5 to FIG. 7, the functional mesh portion 121 and the main mesh portion 122 are provided in a same layer, and a number of mesh wires per unit area of the functional mesh portion 121 is greater than a number of mesh wires per unit area of the main mesh portion 122. Therefore, not only can the resistance in the unit area of the functional mesh portion 121 be smaller than the resistance in the unit area of the main mesh portion 122, and the current density at the connection position P can be accurately and effectively reduced, but also the problem of local region heating can be better solved without increasing a film layer and changing the structural design of other regions. The embodiment of the present disclosure does not limit the thickness, directions or patterns or the like of the mesh wires of the functional mesh portion 121 and the main mesh portion 122. It should be noted that FIG. 7 only schematically shows the metal mesh structure, and other conductive layers are not explained one by one.

For example, as illustrated by FIG. 7, the display panel 100 further includes a base substrate 130 and a pixel driver circuit layer 140 formed on the base substrate, the pixel driver circuit layer 140 includes a plurality of conductive patterns, and the metal mesh structure 120 may be located in a same conductive layer with one of the conductive patterns. For example, as illustrated by FIG. 7, in a bottom-to-top direction, each layer is a base substrate 130, an isolation buffer layer, a gate insulation layer, an interlayer insulation layer, a passivation layer, a first planarization layer, a second planarization layer, a metal mesh structure 120, and a third planarization layer, respectively. For example, the base substrate 130 may include a flexible insulating material such as polyimide (PI) or a rigid insulating material such as a glass base substrate. For example, the metal mesh structure 120 may be a composite film with multiple layers, for example, a TIALTi film. For example, the metal mesh structure 120 may also be a single-layer film. The embodiments of the present disclosure do not limit the conductive layer where the metal mesh structure 120 is located.

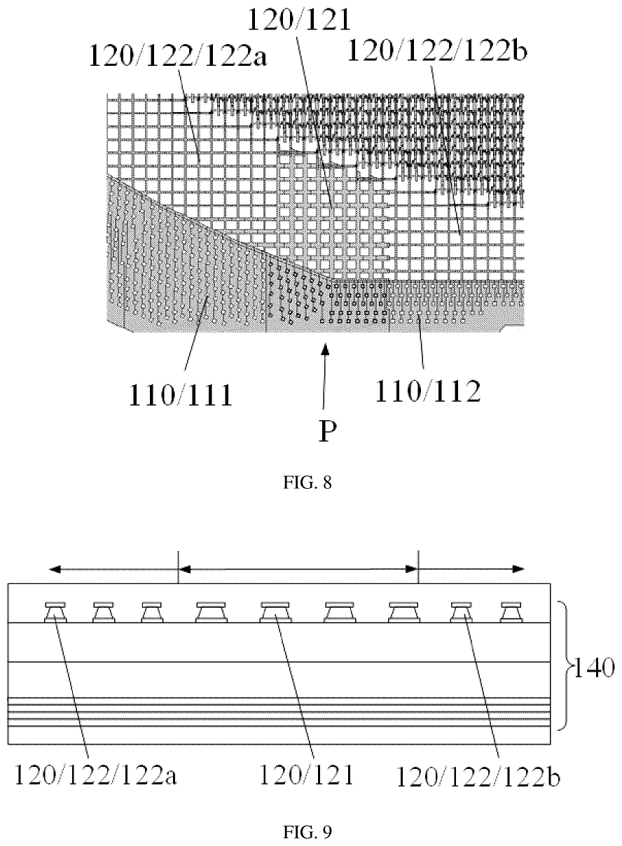

FIG. 8 is a partially enlarged wiring diagram of a display panel according to an embodiment of the present disclosure, and FIG. 9 is a schematic sectional view of FIG. 8. As illustrated by FIG. 8 to FIG. 9, the functional mesh portion 121 and the main mesh portion 122 are arranged in the same layer, and the wire width of the mesh wire in the functional mesh portion 121 is greater than the wire width of the mesh wire in the main mesh portion 122. Therefore, not only can the resistance in the unit area of the functional mesh portion 121 be smaller than the resistance in the unit area of the main mesh portion 122, and the current density at the connection position P can be accurately and effectively reduced, but also the problem of local region heating can be better solved without increasing a film layer and changing the structural design of other regions. The embodiment of the present disclosure does not limit the directions or patterns or the like of the mesh wires of the functional mesh portion 121 and the main mesh portion 122. It should be noted that FIG. 9 only schematically shows the metal mesh structure, and other conductive layers are not explained one by one.

In some examples, as illustrated by FIG. 6 to FIG. 9, the mesh density of the metal mesh structure 120 is in a range from 40% to 85%, and correspondingly, a hole density of the metal mesh structure 120 is in a range from 15% to 60%. A maximum value of the mesh density of the functional mesh portion 121 of the metal mesh structure 120 is set to be 85%, which not only may reduce the current density, but also may avoid excessive load caused by excessive wire density, and the exhaust of the insulation layer under the metal mesh structure 120 will not be affected by the excessive wire density. A minimum value of the mesh density of the main mesh portion 122 of the metal mesh structure 120 is set to be 40%. Setting the minimum value of the mesh density may avoid insignificant decrease of current density caused by too small mesh density.

It should be noted that the mesh density is a proportion of the area of the mesh wires per unit area, the hole density is a proportion of the area of the holes per unit area, and the sum of the mesh density and the hole density is 100%. For example, under the premise that the wire widths of the mesh wires of the metal mesh structure 120 are equal, the mesh density can be equivalent to a density of the mesh wires per unit area, and the change of the mesh density may be equivalent to the change of the density of the mesh wires or the number of meshes.

For example, when the mesh density is 40%, the corresponding hole density is 60%. For example, when the mesh density is 85%, the corresponding hole density is 15%. For example, when the mesh density is 65%, the corresponding hole density is 40%. The mesh density and the hole density are not limited in the embodiments of the present disclosure, and can be designed according to the actual product.

For example, the hole density of the functional mesh portion 121 of the metal mesh structure 120 may be 15%, and the hole density of the main mesh portion 122 may be 20%. For example, the hole density of the functional mesh portion 121 may be 20%, and the hole density of the main mesh portion 122 may be 40%. For example, the hole density of the functional mesh portion 121 may be 15%, and the hole density of the main mesh portion 122 may be 60%. The hole density of the functional mesh portion 121 and the main mesh portion 122 are not limited in the embodiments of the present disclosure, and may be designed according to the current density distribution analyzed by simulation.

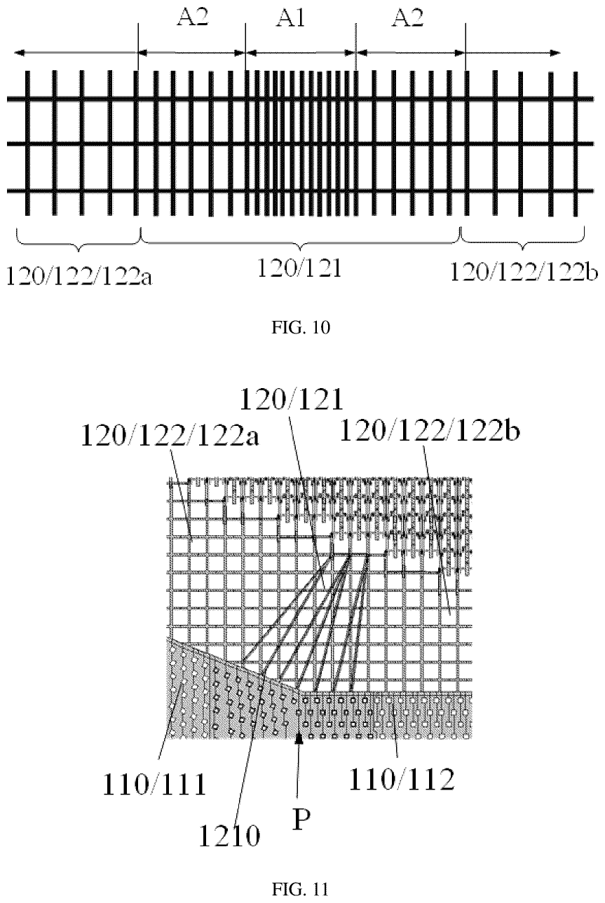

FIG. 10 is a partially enlarged wiring diagram of a metal mesh structure of a display panel according to an embodiment of the present disclosure. As illustrated by FIG. 10, the functional mesh portion 121 and the main mesh portion 122 are arranged in the same layer, and the number of the mesh wires per unit area of the functional mesh portion 121 decreases in a direction of the functional mesh portion towards the main mesh portion 122. Therefore, the metal mesh structure may be improved and optimized for the local heating region in a targeted manner, so as to achieve better improvement results. The embodiments of the present disclosure do not limit the thicknesses, directions or patterns of the mesh wires of the functional mesh portion 121 and the main mesh portion 122. For example, the distribution of the mesh wires of the metal mesh structure 120 may be designed according to the current density distribution analyzed by simulation in combination with the process factors such as exhaust of the insulation layer, so as to better reduce the current density.

FIG. 10 schematically shows that the number of mesh wires per unit area of the functional mesh portion 121 decreases sequentially along a horizontal direction in the figure, which is not limited thereto. For example, the number of mesh wires per unit area of the functional mesh portion 121 decreases in any direction of the functional mesh portion 121 towards the main mesh portion 122. For example, it decreases in a vertical direction, or any other direction between the horizontal direction and vertical direction in the figure.

In some examples, the number of mesh wires per unit area of the functional mesh portion 121 decreases in turn according to a certain law in the direction of the functional mesh portion 121 towards the main mesh portion 122. For example, it may decrease in arithmetic progression.

In some examples, as illustrated by FIG. 10, the mesh density of the main mesh portion 122 may be 40%, and the mesh density of the functional mesh portion 121 may be 80% at the position of the maximum current density, and the mesh density of the functional mesh portion 121 decreases from 80% to 40% in the direction of the functional mesh portion 121 towards the main mesh portion 122.

For example, as illustrated by FIG. 10, in a region A1, the mesh density of the functional mesh portion 121 is 80% and a length of the region A1 is 40 μm; in a next region A2 with a length of 40 μm along the direction of the functional mesh portion 121 towards the main mesh portion 122, the mesh density of the functional mesh portion 121 is 60%; and in the part of the main mesh portion 122 adjacent to the region A2 with a mesh density of 60%, the mesh density is 40%. It is schematically illustrated by the figure that the length of each region in the horizontal direction is 40 μm, which is not limited by the embodiment of the present disclosure, and can be the length in other directions according to the shape of the metal mesh structure at the position where the display panel is located. A size or area of the region A1 and the region A2 is not limited in the present disclosure, and they can be other values, and the values of the region A1 and the region A2 may also be different, and may be specifically designed based on a size or area of the heating region.

For example, the variation gradient of the mesh density of the functional mesh portion 121 may be 80%, 70%, 60%, 50%, and 40%. For example, in a region of a preset dimension at the connection position P of the first wire segment 111 and the second wire segment 112, the mesh density of the functional mesh portion 121 may be 80%, and in a region of the next preset dimension in the direction of the functional mesh portion 121 towards the main mesh portion 122, the mesh density of the functional mesh portion 121 is 70%, and so on, in a next region of the preset dimension, the mesh density of the functional mesh portion 121 is 60% and 50%, respectively, and the mesh density of the main mesh portion 122 is 40%. The preset dimension of each region is not limited in the embodiments of the present disclosure, and the preset dimensions of the regions where respective mesh density are located may be the same or different, and the mesh density of adjacent regions changes regularly, which can better solve the problem of local region heating.

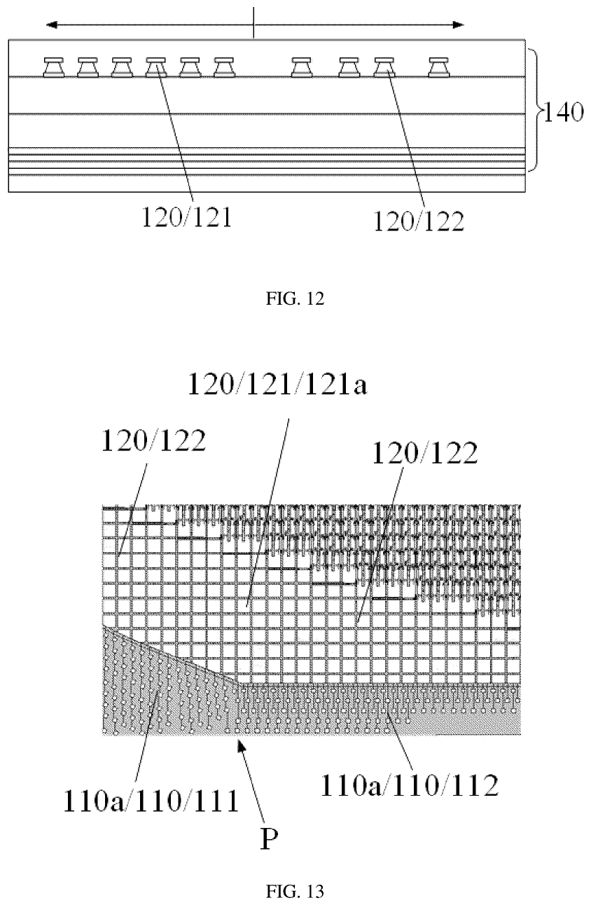

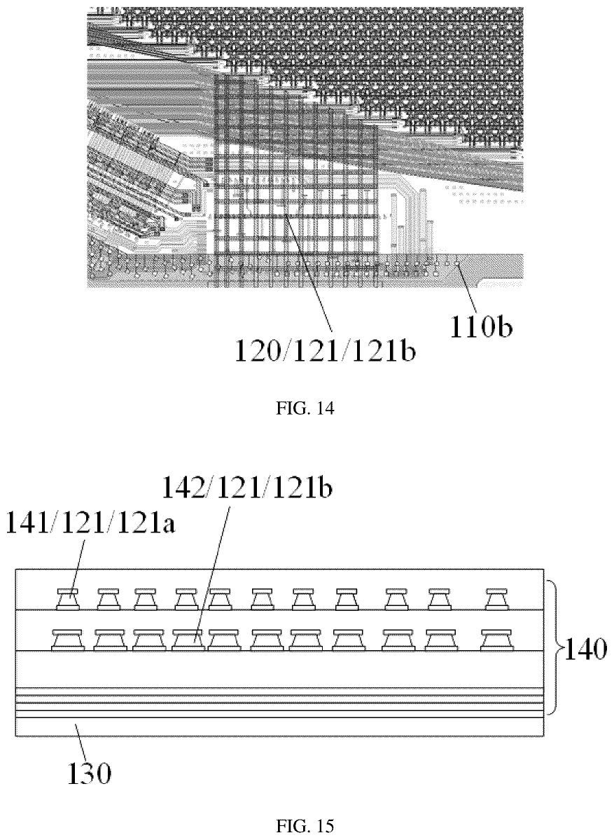

FIG. 11 is a partially enlarged wiring diagram of a display panel according to an embodiment of the present disclosure, and FIG. 12 is a schematic sectional view of FIG. 11. As illustrated by FIG. 11 and FIG. 12, the functional mesh portion 121 and the main mesh portion 122 are arranged in the same layer, the main mesh portion 122 includes a first mesh pattern, the functional mesh portion 121 includes a second mesh pattern, the second mesh pattern includes the first mesh pattern and a plurality of straight wire segments 1210, and the plurality of straight wire segments extend from a side of the functional mesh portion 121 close to the display region AA to the common power supply wire 110 in a divergent manner. A direction of the plurality of straight wire segments 1210 is approximately the same as a direction of the current, therefore, in the region with the maximum current density, the patterns and directions of the mesh wires of the functional mesh portion 121 are designed according to the current direction, which can effectively reduce the current density in the region with the maximum current density, and can better reduce the current density and solve the problem of local heating. It should be noted that FIG. 12 only schematically shows the metal mesh structure, and other conductive layers are not explained one by one. FIG. 13 is a partial enlarged view of a first mesh layer of a display panel [0109] according to an embodiment of the present disclosure; FIG. 14 is a partial enlarged view of a second mesh layer of a display panel illustrated by FIG. 13; FIG. 15 is a partial sectional view of a display panel illustrated by FIG. 13. As illustrated by FIG. 13 to FIG. 15, the functional mesh portion 121 includes a first mesh layer 121a and a second mesh layer 121b which are electrically connected with each other. The first mesh layer 121a and the main mesh portion 122 are arranged in a same layer, and the first mesh layer 121a and the second mesh layer 121b are arranged in different layers. The parallel connection of the first mesh layer 121a and the second mesh layer 121b can make the resistance in the unit area of the functional mesh portion 121 smaller than the resistance in the unit area of the main mesh portion 122, thereby reducing the current density at the connection position P and solving the problem of local region heating. In order to clearly show the first mesh layer 121a and the second mesh layer 121b, the first mesh layer 121a and the second mesh layer 121b are illustrated by FIG. 13 and FIG. 14, respectively. FIG. 14 shows not only the second mesh layer 121b, but also the local structures of other conductive layers, which will not be described here.

In some examples, as illustrated by FIG. 13, a mesh pattern of the first mesh layer 121a is the same as a mesh pattern of the main mesh portion 122. In this case, in a direction perpendicular to the display panel 100, the first mesh layer 121a and the second mesh layer 121b have approximately the same coverage region. For example, the mesh patterns of the first mesh layer 121a and the main mesh portion 122 may be different. The embodiment of the present disclosure does not limit the mesh pattern of the first mesh layer 121a and the mesh pattern of the second mesh layer 121b.

For example, the mesh pattern of the first mesh layer 121a may include the mesh pattern in any of the preceding embodiments, and the second mesh layer 121b may include the mesh pattern in any of the preceding embodiments, which will not be described again herein.

In some examples, as illustrated by FIG. 13 to FIG. 15, in the direction perpendicular to the display panel 100, the first mesh layer 121a and the second mesh layer 121b have approximately the same mesh pattern, and the first mesh layer 121a and the second mesh layer 121b are approximately overlapped. Thus, the capacitance difference between the first mesh layer 121a and the second mesh layer 121b can be reduced.

In some examples, as illustrated by FIG. 13 and FIG. 14, the conductive layer where the first mesh layer 121a is located includes the common power supply wire 110a, the conductive layer where the second mesh layer 121b is located includes a common power supply wire 110b, the mesh wires of the first mesh layer 121a are connected to the common power supply wire 110a, and the mesh wires of the second mesh layer 121b are connected to the common power supply wire 110b, and the common power supply wire 110a is connected to the common power supply wire 110b so that the first mesh layer 121a and the second mesh layer 121b are electrically connected to each other. The embodiments of the disclosure do not limit the manner in which the first mesh layer 121a and the second mesh layer 121b are electrically connected to each other.

In some examples, as illustrated by FIG. 13 to FIG. 15, the display panel 100 further includes the base substrate 130 and the pixel circuit driver layer 140 formed on the base substrate 130. The pixel circuit driver layer 140 includes a plurality of conductive patterns arranged sequentially in the direction perpendicular to the base substrate 130, and the plurality of conductive patterns include a first conductive pattern and a second conductive pattern. The first mesh layer 121a and the main mesh portion 122 are located in a same conductive layer 141 as the first conductive pattern, and the second mesh layer 121b is located in a same conductive layer 142 as the second conductive pattern. The second mesh layer 121b is located in the same conductive layer 142 as the second conductive pattern, so that the problem of local region heating can be solved without the need for an additional layer. For example, the conductive layer 141 and the conductive layer 142 are also known as a source-drain metal layer.

For example, as illustrated by FIG. 15, the metal mesh structure 120 in the embodiments of the present disclosure may be a composite film with multiple layers, for example, a TIALTi film. Of course, embodiments of the present disclosure are not limited thereto, and may also be a single-layer film.

In some examples, as illustrated by FIG. 13 to FIG. 15, the first mesh layer 121a is located at a side of the second mesh layer 121b away from the base substrate 130. In the direction perpendicular to the base substrate 130, an orthographic projection of the mesh wire of the first mesh layer 121a on the base substrate 130 falls into an orthographic projection of the mesh wire of the second mesh layer 121b on the base substrate 130, which avoids the mesh wire of the first mesh layer 121a from falling on a side or slope of the mesh wire of the second mesh layer 121b, avoid affecting the etching of the first mesh layer 121a.

For example, in the direction perpendicular to the base substrate 130, a width of the mesh wire of the second mesh layer 121b is greater than or equal to 2 μm than a width of the mesh wire of the first mesh layer 121a, and a boundary of a side of the mesh wire of the second mesh layer 121b exceeds a boundary of the corresponding side of the mesh wire of the first mesh layer 121a by 1 μm. Thus, process fluctuations or deviations can be absorbed to avoid the mesh wire of the first mesh layer 121a from falling on the side or slope of the mesh wire of the second mesh layer 121b.

In some examples, as illustrated by FIG. 14, the second mesh layer 121b is insulated from the second conductive pattern located in the display region, and the mesh wires of the second mesh layer 121b are disconnected from the second conductive pattern.

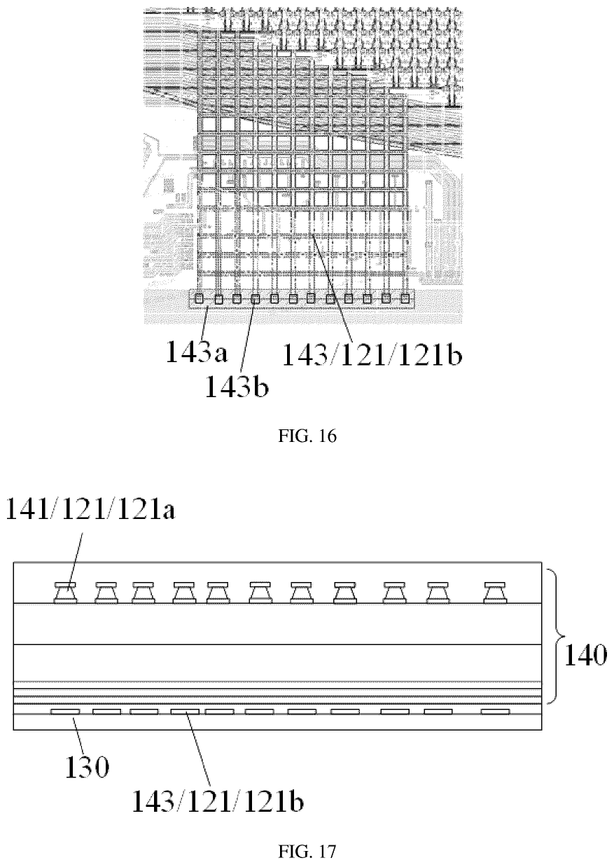

FIG. 16 is a partial enlarged diagram of another second conductive layer of the display panel illustrated by FIG. 13; and FIG. 17 is a partial sectional view of a display panel illustrated by FIG. 13. As illustrated by FIG. 13, FIG. 16 and FIG. 17, the display panel 100 further includes a base substrate 130, a pixel circuit driver layer 140 formed on the base substrate 130 and a shielding metal layer located between the base substrate 130 and the pixel circuit driver layer 140. The pixel circuit driver layer 140 includes a plurality of conductive patterns arranged sequentially in the direction perpendicular to the base substrate 130, and the plurality of conductive patterns include a first conductive pattern. The first mesh layer 121a and the main mesh portion 122 are located in a same conductive layer 141 as the first conductive pattern, and the second mesh layer 121b is located in a same conductive layer 143 as the shielding metal layer. The shielding metal layer is located between the base substrate 130 and the pixel circuit driver layer 140, and the shielding metal layer is closer to the base substrate 130 than other conductive layers, so that locating the second mesh layer 121b and the shielding metal layer in the same conductive layer 143 may not only reduce the current density, but also shunt the current downward, so that the heat at the position with relatively high heating may be diverged downward and outward relatively fast. In addition, the second mesh layer 121b is located in the same conductive layer 143 as the shielding metal layer, so that the problem of local region heating can be solved without the need for an additional layer. It is noted that FIG. 16 shows not only the second mesh layer 121b, but also the partial structures of other conductive layers, which will not be described again here. FIG. 17 only schematically shows the first mesh layer 121a and the second mesh layer 121b, and the other conductive layers are not described one by one.

In some examples, as illustrated by FIG. 16 and FIG. 17, the shielding metal layer 150 includes a shielding pattern to shield charges in the base substrate 130 and eliminates the adverse effect of the charges in the base substrate 130 on a transistor in the pixel circuit driver layer 140. The second mesh layer 121b is insulated with the shield pattern, and the mesh wire of the second mesh layer 121b is not connected to the shield pattern. For example, the second mesh layer 121b is configured to receive a first power supply voltage (VSS) and the shield pattern is configured to receive a second power supply voltage (VDD).

In some examples, as illustrated by FIG. 13 and FIG. 16, the conductive layer 143 further includes a connection structure 143a and a connection via 143b, the mesh wire of the second mesh layer 121b is connected with the connection structure 143a, the connection via 143b connects the connection structure 143a with the common power supply wire 110, and the first mesh layer 121a is connected with the common power supply wire 110. Thus, the second mesh layer 121b can be electrically connected with the first mesh layer 121a through the connection structure 143a, the connection via 143b and the common power supply wire 110. Of course, the embodiment of the present disclosure does not limit the connection mode of the first mesh layer 121a and the second mesh layer 121b.

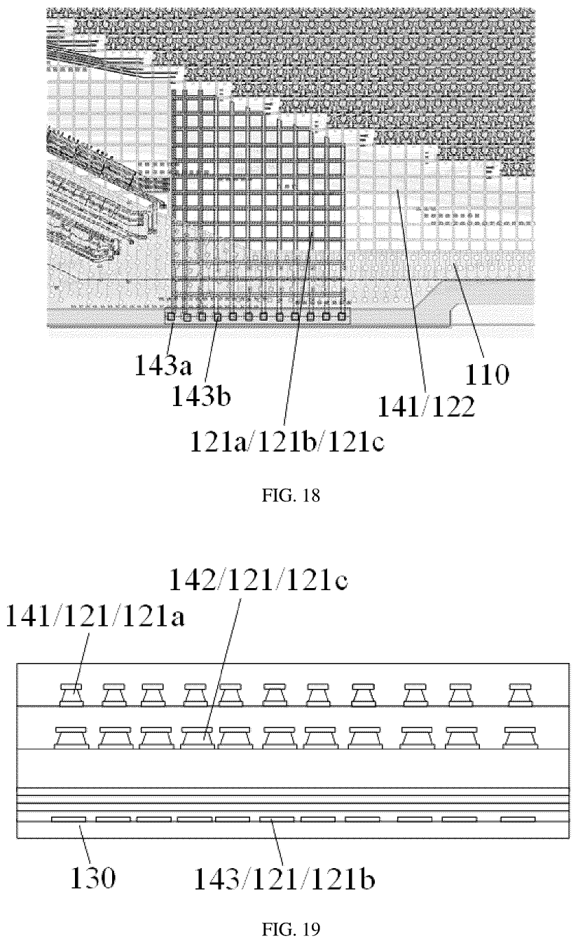

FIG. 18 is a partial wiring diagram of a display panel illustrated by FIG. 13; FIG. 19 is a partial sectional view of a display panel illustrated by FIG. 18. As illustrated by FIG. 13, FIG. 18 and FIG. 19, the functional mesh portion 121 further includes a third mesh layer 121c located between the first mesh layer 121a and the second mesh layer 121b, the plurality of conductive patterns further include a second conductive pattern, and the third mesh layer 121c is located in the same conductive layer 142 as the second conductive pattern. By connecting the first mesh layer 121a, the second mesh layer 121b and the third mesh layer 121c in parallel, the resistance per unit area of the functional mesh portion 121 can be further reduced, and the current density at the connection position P can be better reduced. In addition, the third mesh layer 121c is located in the same conductive layer 142 as the second conductive pattern, so that the problem of local region heating can be solved without the need for an additional layer. FIG. 19 only schematically shows the first mesh layer 121a, the second mesh layer 121c, and the third mesh layer 121c, and the other conductive layers are not described one by one.

For example, the plurality of conductive patterns further include a third conductive pattern, and the peripheral region BB further includes a gate driving circuit formed on the base substrate 130, and a wire connecting the gate driving circuit and the display region AA is located in a same conductive layer as the third conductive pattern. Of course, the present disclosure is not limited thereto.

In some examples, as illustrated by FIG. 19, a mesh pattern of the third mesh layer 121c is substantially the same as a mesh pattern of the first mesh layer 121a. For example, an orthographic projection of the mesh wire of the first mesh layer 121a on the base substrate 130 falls into an orthographic projection of the mesh wire of the third mesh layer 121c on the base substrate 130. For example, the mesh wire of the third mesh layer 121c is disconnected from the second conductive pattern.

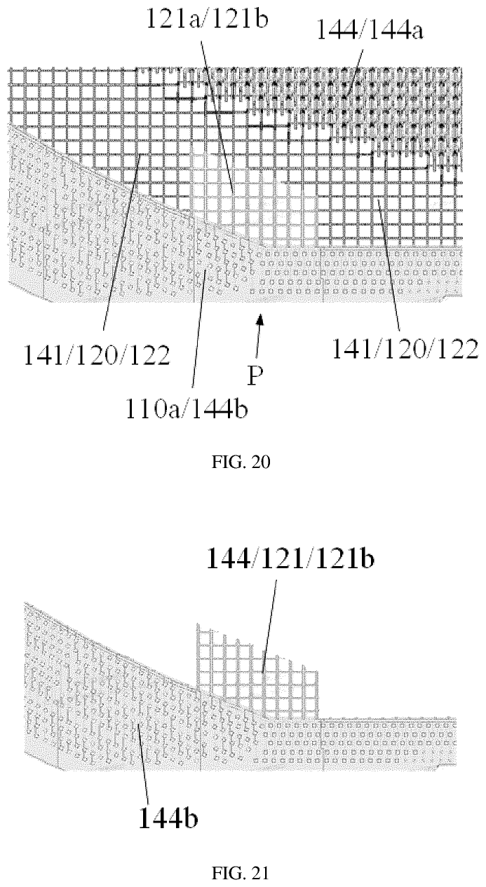

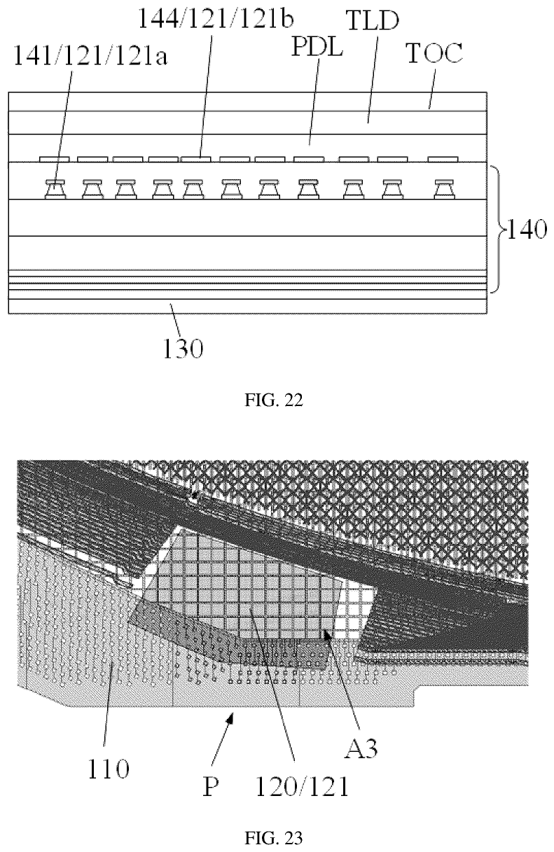

FIG. 20 is a partial wiring diagram of a display panel according to an embodiment of the present disclosure; FIG. 21 is a partial wiring diagram of a second mesh layer of a display panel illustrated by FIG. 20; FIG. 22 is a partial sectional view of a display panel illustrated by FIG. 20. As illustrated by FIG. 20 to FIG. 22, the display panel 100 further includes a base substrate 130, a pixel circuit driver layer 140 formed on the base substrate 130 and a first electrode layer 144a formed on a side of the pixel circuit driver layer 140 away from the base substrate 130. The pixel circuit driver layer 140 includes a plurality of conductive patterns arranged sequentially in the direction perpendicular to the base substrate 130, and the plurality of conductive patterns include a first conductive pattern. The first mesh layer 121a and the main mesh portion 122 are located in a same conductive layer 141 as the first conductive pattern, and the second mesh layer 121b is located in a same conductive layer 144 as the first electrode layer 144a. The second mesh layer 121b is located in the same conductive layer 144 as the first electrode layer 144a, so that the problem of local region heating can be solved without the need for an additional layer. In addition, the second mesh layer 121b is located above the first mesh layer 121a, so that the current can be shunted upwards to dissipate heat upwards. For example, the first electrode layer 144a may be an anode, which, of course, is not limited in the embodiments of the present disclosure. FIG. 22 only schematically shows the first mesh layer 121a and the second mesh layer 121b, and the other conductive layers are not described one by one.

In some examples, as illustrated by FIG. 20 to FIG. 22, the mesh pattern of the second mesh layer 121b substantially overlaps with the mesh pattern of the first mesh layer 121a in the direction perpendicular to the base substrate 130, thereby the capacitance difference between the first mesh layer 121a and the second mesh layer 121b can be reduced.

In some examples, as illustrated by FIG. 20, the mesh wire of the second mesh layer 121b is not connected to the pattern of the first electrode layer 144a located in the display region.

In some examples, as illustrated by FIG. 20 to FIG. 22, the conductive layer 144 further includes a connection structure 144b, and the second mesh layer 121b is connected to the connection structure 144b. The conductive layer 141 includes the first mesh layer 121a and the common power supply wire 110a, the common power supply wire 110a at least partially overlaps with the connection structure 144b in the direction perpendicular to the base substrate 130, and the first mesh layer 121a and the second mesh layer 121b can be electrically connected by connecting the common power supply wire 110a with the connection structure 144b. Of course, the embodiments of the present disclosure do not limit the connection mode of the first mesh layer 121a and the second mesh layer 121b.

For example, as illustrated by FIG. 22, a pixel define layer PDL may be provided on a side of the second mesh layer 121b away from the base substrate 130. For example, a touch insulation TLD and a touch protection layer TOC may also be provided on a side of the pixel define layer PDL away from the base substrate 130, which will not be described here.

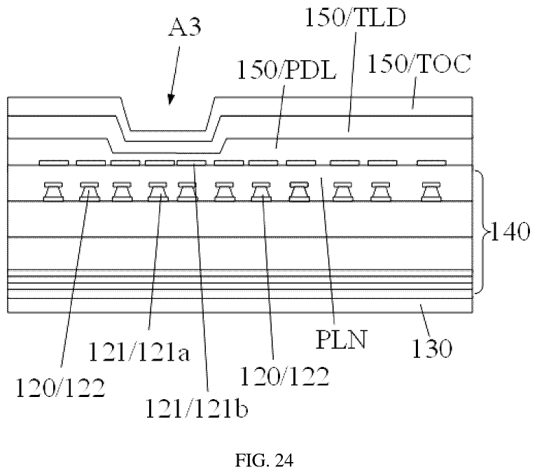

FIG. 23 is a partial wiring diagram of a display panel according to an embodiment of the present disclosure, and FIG. 24 is a partial sectional view of FIG. 23. As illustrated by FIG. 23 and FIG. 24, the display panel 100 further includes a base substrate 130 and a plurality of insulation layers 150, the metal mesh structure 120 is located on the base substrate 130, and the plurality of insulation layers 150 are located at a side that the metal mesh structure 120 away from the base substrate 130. A thickness of a region of the plurality of insulating layers overlapping with the functional mesh portion is smaller than a thickness of other region of the plurality of insulation layers 150 along the direction perpendicular to the base substrate 130. By thinning the plurality of insulation layers 150 located on the functional mesh portion 121, the heat at the position with relatively high heat generation can be dissipated upward and outward more quickly.

The figure schematically shows that the functional mesh portion 121 includes the first mesh layer 121a and the second mesh layer 121b, which is not limited by the embodiment of the present disclosure. For example, the metal mesh structure 120 can also be any of the structures described above, and will not be described in detail here.

It should be noted that, in order to clearly show the position relationship between a thinning region A3 of the insulation layer 150 and the functional mesh portion 121 in FIG. 23, the thinning region A3 of the insulation layer 150 is schematically illustrated by the figure, and the thinning region A3 does not represent the disconnection of the insulation layer 150, but the region where the thinning region A3 is located, and the thinning region A3 overlaps with the functional mesh portion 121 to dissipate the heat at the position with relatively high heating upwards and outwards more quickly.

For example, the thinning region of the plurality of insulation layers 150 covers the functional mesh portion 121 to better dissipate heat.

For example, as illustrated by FIG. 23 and FIG. 24, the plurality of insulation layers 150 include a pixel define layer PDL, a touch insulation layer TLD, and a touch protective layer TOC formed sequentially on the planarization layer PLN. Of course, this is not limited in the embodiments of the present disclosure.

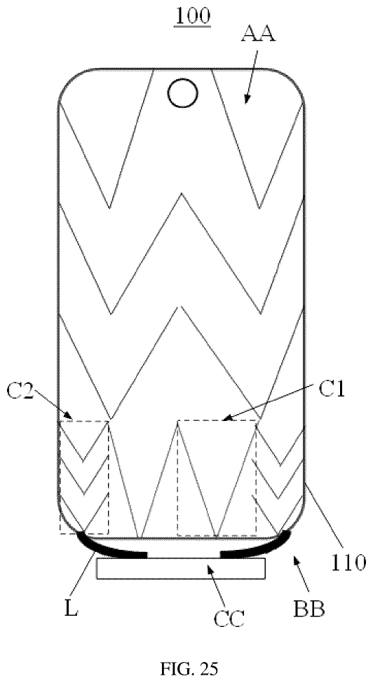

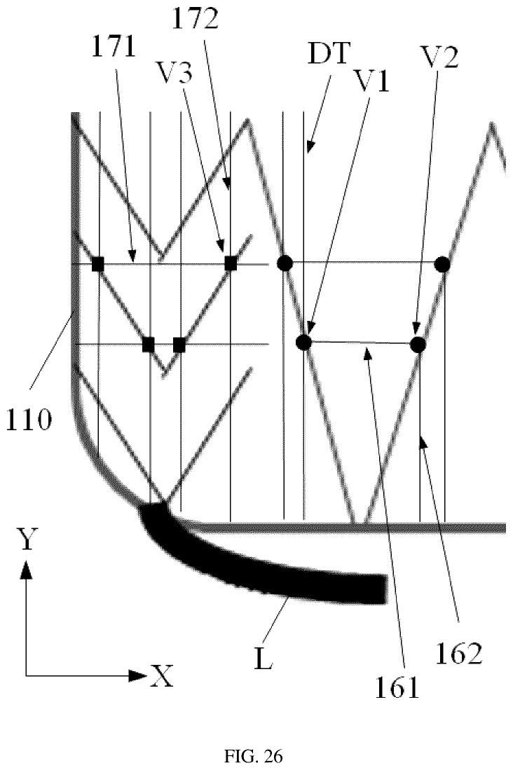

FIG. 25 is a schematic diagram of a display panel according to an embodiment of the present disclosure, and FIG. 26 is a partial schematic enlarged view of FIG. 25. As illustrated by FIG. 25 and FIG. 26, the display panel 100 further includes first transfer wires 161, second transfer wires 162, first dummy wires 171 and second dummy wires 172. The first transfer wire 161 extends in a first direction X, and the second transfer wire 162 extends in a second direction Y, and is arranged in a different layer with the first transfer wire 161. The first dummy wire 171 extends in the first direction X, and the second dummy wire 172 extends in the second direction Y, and is arranged in a different layer from the first dummy wire 171. The display panel 100 further includes data wires DT extending in the second direction Y. An end of the first transfer wire 161 is connected with the data wire DT through a first via V1, another end of the first transfer wire 161 is connected with the second transfer wire 162 through a second via V2. The first via holes V1 and the second via holes V2 form a first transfer region C1, the display panel 100 includes a display region AA and a peripheral region BB surrounding the display region AA. The peripheral region BB includes a bonding region CC, and the first transfer region C1 is located at a side of the display region AA close to the bonding region CC. The display panel 100 further includes a light-emitting component, the first dummy wires 171 and the second dummy wires 172 are connected with a cathode of the light-emitting component and are configured to transmit a power supply voltage. The first dummy wires 171 and the second dummy wires 172 are connected through third via holes V3, and the third via holes V3 form a plurality of second transfer regions C2.

It should be noted that the first transfer region C1 and the second transfer region C2 are functional partitions to facilitate understanding in the description. In order to clearly show the direction of the first transfer wire 161 and the second transfer wire 162, the first transfer region C1 only schematically shows two data wires DT, two first transfer wires 161 and two second transfer wires 162, and a V-shaped line in the first transfer region C1 is a connection line connecting the first via holes V1 and the second via holes V2, not the wire in the display panel 100. In order to clearly show the direction of the first dummy wire 171 and the second dummy wire 172, the second transfer region C2 only schematically shows two first dummy wires 171 and four second dummy wires 172. For example, third via holes V3 are provided at overlapping positions of the respective first dummy wires 171 and the respective second dummy wires 172 in the second transfer region C2, so that the third via holes V3 are arranged in an array in the first direction X and the second direction Y in the second transfer region C2. For example, third via holes V3 are provided only at partially overlapping positions of the respective first dummy wires 171 and the respective second dummy wires 172 in the second transfer region C2, the third via holes V3 are arranged in a V-shape in the second transfer region C2, that is, a V-shaped line in the second transfer region C2 is a connection line connecting the third via holes V3, instead of the wire in the display panel 100.

In the display panel 100 provided in the embodiments of the present disclosure, by providing the first transfer wires 161 and the second transfer wires 162, the data wires DT may be transferred to a region close to a center of the display panel, and then to the bonding region CC through a lead wire, thereby reducing a width occupied by the lead wire in a border where the lead wire is located, and further reducing a size of the border of the display panel 100. Providing the first dummy wires 171 and the second dummy wires 172 connected to the cathode of the light-emitting component in a region where the first transfer wires 161 and the second transfer wires 162 are not provided can not only reduce the voltage drop of the power supply voltage (VSS) and the power consumption of the display panel 100, but also improve the uniformity of the display.

In some examples, as illustrated by FIG. 25 and FIG. 26, the display panel 100 further includes a common power supply wire 110 located in the peripheral region BB, and the first dummy wire 171 extends in the first direction X and is connected with the common power supply wire 110. For example, the second dummy wire 172 extends in the second direction Y and is connected with the common power supply wire 110.

In some examples, as illustrated by FIG. 4, FIG. 5, FIG. 25 and FIG. 26, the part of the wires of the metal mesh structure 120 extending into the display region AA includes a part of the second dummy wires 172. This is not limited in the embodiments of the present disclosure. For example, the part of the wires of the metal mesh structure 120 extending into the display region AA include a part of the first dummy wires 171.

In some examples, the first transfer wires 161 are arranged in the same layer as the first dummy wires 171, and the first transfer wires 161 and the first dummy wires 171 arranged in the same layer are insulated from each other.

In some examples, the second transfer wires 162 are arranged in the same layer as the second dummy wires 172, and the second transfer wires 162 and the second dummy wires 172 arranged in the same layer are insulated from each other.

In some examples, the display panel 100 further includes a base substrate and a pixel circuit driver layer formed on the base substrate. The pixel circuit driver layer includes a plurality of conductive patterns arranged sequentially in the direction perpendicular to the base substrate, and the plurality of conductive patterns include a first conductive pattern and a second conductive pattern. The first transfer wires 161 and the first dummy wires 171 are located in a same conductive layer as the first conductive pattern, and the second transfer wires 162 and the second dummy wires 172 are located in a same conductive layer as the second conductive pattern. For example, the conductive layer where the conductive pattern is located is also known as the source-drain metal layer.

In some examples, as illustrated by FIG. 25 and FIG. 26, the connection line connecting the plurality of first via holes V1 and the plurality of the second via holes V2 of the first transfer region C1 is in a preset shape, and the connection lines connecting multiple third via holes V3 in the second transfer region C2 is approximately in a preset shape. For example, the first transfer region C1 includes one connection line in the preset shape. For example, the second transfer region C2 includes a plurality of connection lines in the preset shape. For example, the plurality of connection lines of the second transfer region C2 in the preset shape are arranged along the second direction Y. For example, the set shape can be a V-shape in the figure. The embodiment of the present disclosure does not limit the set shape.

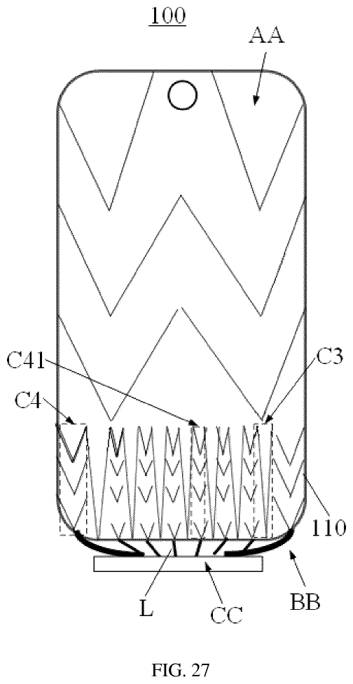

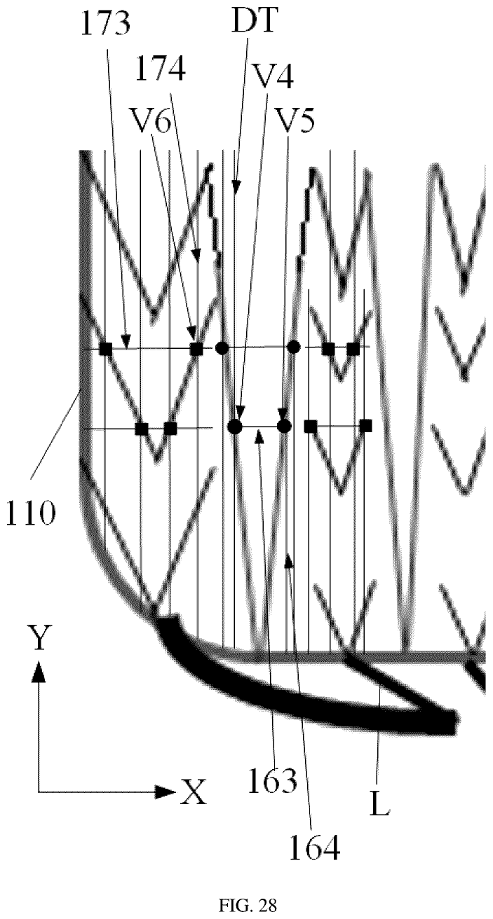

FIG. 27 is another schematic diagram of a display panel according to an embodiment of the present disclosure, and FIG. 28 is a partial schematic enlarged view of FIG. 27. As illustrated by FIG. 27 and FIG. 28, the display panel 100 includes third transfer wires 163, fourth transfer wires 164, third dummy wires 173 and fourth dummy wires 100, and the display panel 100 further includes data wires DT. The third transfer wire 163 extends in a first direction X, and the fourth transfer wire 164 extends in a second direction Y, and is arranged in a different layer with the third transfer wire 163. The third dummy wire 173 extends in the first direction X, and the fourth dummy wire 174 extends in the second direction Y, and is arranged in a different layer from the third dummy wire 173. The data wire DT extends in the second direction Y, an end of the third transfer wire 163 is connected with the data wire DT through a fourth via V4, another end of the third transfer wire 163 is connected with the fourth transfer wire 164 through a fifth via V5. The fourth via holes V4 and the fifth via holes V5 form a plurality of third transfer regions C3. The plurality of third transfer regions C3 are spaced with each other in the first direction X. The display panel 100 includes a display region AA and a peripheral region BB surrounding the display region AA, the peripheral region BB includes a bonding region CC, and the plurality of third transfer regions C3 are located at a side of the display region AA close to the bonding region CC.

The display panel 100 includes a light-emitting component, the third dummy wires 173 and the fourth dummy wires 174 are connected with a cathode of the light-emitting component and are configured to transmit a power supply voltage. The third dummy wires 173 and the fourth dummy wires 174 are connected through sixth via holes V6, and the sixth via holes V6 form a plurality of fourth transfer regions C4. In the first direction X, at least one fourth transfer region C4 is located among the plurality of third transfer regions C3.

It should be noted that the third transfer region C3 and the fourth transfer region C4 are functional partitions to facilitate understanding in the description. In order to clearly show the direction of the third transfer wire 163 and the fourth transfer wire 164, the third transfer region C3 only schematically shows two data wires DT, two third transfer wires 163 and two fourth transfer wires 164, and a V-shaped line in the third transfer region C3 is a connection line of the fourth via holes V4 and the fifth via holes V5, not the wire in the display panel 100. In order to clearly show the direction of the third dummy wire 173 and the fourth dummy wire 174, the fourth transfer region C4 only schematically shows two third dummy wires 173 and four fourth dummy wires 174. For example, the sixth via holes V6 are provided at overlapping positions of the respective third dummy wires 173 and the respective fourth dummy wires 174 in the fourth transfer region C4, so that the sixth via holes V6 are arranged in an array in the first direction X and the second direction Y in the fourth transfer region C4. For example, the sixth via holes V6 are provided only at partially overlapping positions of the respective third dummy wires 173 and the respective fourth dummy wires 174 in the fourth transfer region C4, the sixth via holes V6 are arranged in a V-shape in the fourth transfer region C4, that is, a V-shaped line in the fourth transfer region C4 is a connection line connecting the third via holes V3, instead of the wire in the display panel 100.

In the display panel 100 provided in the embodiments of the present disclosure, by providing the third transfer wires 163 and the fourth transfer wires 164 in the third transfer region C3, the data wires DT may be transferred to a region close to a center of the display panel, and then to the bonding region CC through a lead wire, thereby reducing a width occupied by the lead wire in a border where the lead wire is located, and further reducing a size of the border of the display panel 100. Providing the third dummy wires 173 and the fourth dummy wires 174 connected to the cathode of the light-emitting component in a region where the third transfer wires 163 and the fourth transfer wires 164 are not provided can not only reduce the voltage drop of the power supply voltage (VSS) and the power consumption of the display panel 100, but also improve the uniformity of the display.

In the first direction X, at least one fourth transfer region C4 is located among the plurality of third transfer regions C3, so that the fourth dummy wire 174 of the fourth transfer region C4 located among the plurality of third transfer regions C3 may be led to the bonding region CC through a lead wire L, which further disperses the current of the common power supply wire 110 located in the peripheral region BB and reduces the current density of the common power supply wire 110 located in the peripheral region BB, so that the common power supply wire 110 in the peripheral region BB does not have exceedingly high current density when passing through a corner of the display panel 100, and the common power supply wire 110 in the peripheral region BB does not have exceedingly high current density at a position where the width of the common power supply wire 110 changes, solving the local region heating problem such as at a corner or a position where the width changes.

For example, as illustrated by FIG. 5, FIG. 27 and FIG. 28, leading the fourth dummy wire 174 of the fourth transfer region C4 located among the plurality of third transfer region C3 to the bonding region CC through the lead wire L can reduce the current of the common power supply wire 110 in the peripheral region BB in FIG. 5, and reduce the current density at the connection position P, and solve the problem of local region heating.

In some examples, as illustrated by FIG. 27 and FIG. 28, a plurality of fourth transfer regions C4 are located among the plurality of third transfer regions C3 in the first direction X. For example, in the first direction X, the plurality of fourth transfer regions C4 and the plurality of third transfer regions C3 are alternately distributed.

In some examples, as illustrated by FIG. 27 and FIG. 28, the display panel 100 further includes the lead wire L. The lead wire L is located between the display region AA and the bonding region CC. The bonding region CC includes a common power supply terminal that is configured to transmit a common power supply signal and an end of the lead wire L is connected to the common power supply terminal. The plurality of fourth transfer regions C4 include a first sub-region C41. In the first direction X, the first sub-region C41 is located among the plurality of third transfer regions C3, and a part of the fourth dummy wires 174 in the first sub-region C41 is connected with another end of the lead wire L. The fourth dummy wire 174 in the first sub-region C41 among the plurality of third transfer regions C3 can be led out of the display region AA and connected to the common power supply terminal of the bonding region CC through the lead wire L, so that the current of the common power supply wire 110 located in the peripheral region BB can be dispersed, and further the heating problem in local region such as corner position or width change position can be solved.

In some examples, as illustrated by FIG. 28, the third transfer wires 163 are arranged in the same layer as the third dummy wires 173. The third transfer wires 163 and the third dummy wires 173 arranged in the same layer are insulated from each other.

In some examples, as illustrated by FIG. 28, the fourth transfer wires 164 are arranged in the same layer as the fourth dummy wires 174. The fourth transfer wires 164 and the fourth dummy wires 174 arranged in the same layer are insulated from each other.

In some examples, the display panel 100 further includes a base substrate 130 and a pixel circuit driver layer 140 formed on the base substrate 130. The pixel circuit driver layer 140 includes a plurality of conductive patterns arranged sequentially in the direction perpendicular to the base substrate 130, and the plurality of conductive patterns include a first conductive pattern 141 and a second conductive pattern 142. The third transfer wires 163 and the third dummy wires 173 are located in a same layer as the first conductive pattern, and the fourth transfer wires 164 and the fourth dummy wires 174 are located in a same layer as the second conductive pattern 142.

In some examples, as illustrated by FIG. 27 and FIG. 28, the connection line connecting the plurality of fourth via holes V4 and the plurality of the fifth via holes V5 of the third transfer region C3 is in a preset shape, and the connection line connecting multiple sixth via holes V6 in the fourth transfer region C4 is approximately in a preset shape. For example, the third transfer region C3 includes one connection line in the preset shape. For example, the fourth transfer region C4 includes a plurality of connection lines in the preset shape. For example, the plurality of connection lines of the fourth transfer region C4 in the preset shape are arranged along the second direction Y. For example, the set shape can be a V-shape in the figure. The embodiment of the present disclosure does not limit the set shape.

In some examples, as illustrated by FIG. 4, FIG. 5, FIG. 27, and FIG. 28, the part of the wires extending from the metal mesh structure 120 into the display region AA includes a part of the fourth dummy wires 174. This is not limited in the embodiments of the present disclosure. For example, the part of the wires extending from the metal mesh structure 120 into the display region AA includes a part of the third dummy wires 173.

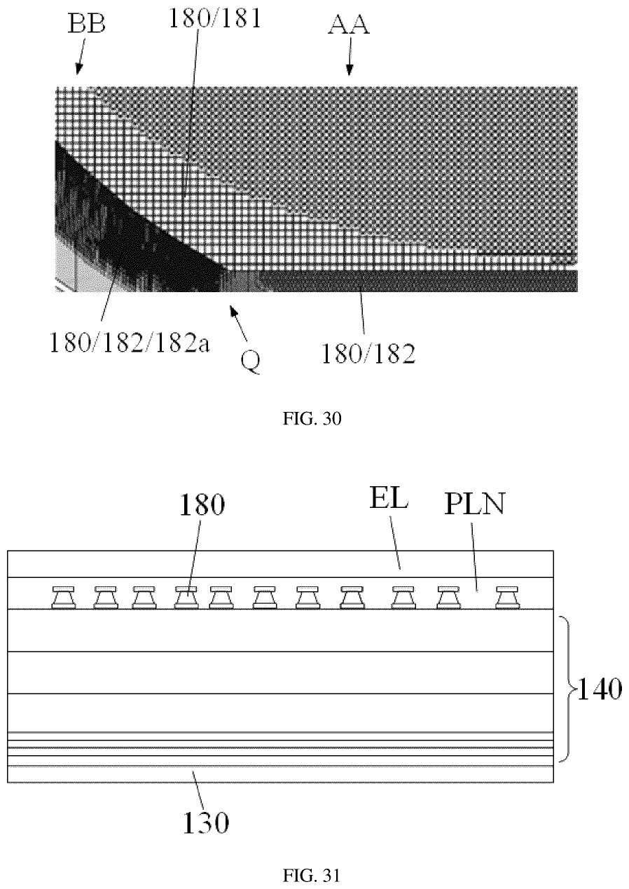

FIG. 29 is a schematic plan view of a common power mesh layer of a display panel according to an embodiment of the present disclosure; FIG. 30 is a partial schematic diagram of a common power mesh layer illustrated by FIG. 29; FIG. 31 is a schematic sectional view of FIG. 29. As illustrated by FIG. 29 to FIG. 31, the display panel 100 includes a base substrate 130, a pixel circuit driver layer 140, and a common power supply mesh layer 180. The pixel circuit driver layer 140 is located on the base substrate 130, and the common power supply mesh layer 180 is located at a side of the pixel circuit driver layer 140 away from the base substrate 130. The display panel 100 includes a display region AA and a peripheral region BB surrounding the display region AA, and the common power supply mesh layer includes mesh wires 181 located in the display region AA and a peripheral common power supply wire 182 located in the peripheral region BB. The peripheral region BB includes a bonding region CC, and the display panel 100 further includes a lead wire L located between the display region AA and the bonding region CC. The bonding region CC includes a common power supply terminal configured to transmit a common power supply signal, an end of the lead wire L is connected to the common power supply terminal, and another end of the lead wire L is connected to the mesh wires 181 of the common power mesh layer 180. It should be noted that FIG. 29 only schematically shows a part of the mesh wires of the common power supply mesh layer 180, and FIG. 31 only schematically shows the common power supply mesh layer 180, and the other conductive layers are not described again one by one.

In the display panel 100 provided in the embodiments of the present disclosure, by setting the common power mesh layer 180 and connecting the mesh wires 181 of the common power mesh layer 180 with the common power terminal of the bonding region CC through the lead wire L, the current of the peripheral common power supply wire 182 located in the peripheral region BB can be dispersed, and the current density of the peripheral common power supply wire 182 located in the peripheral region BB can be reduced. So that the current density of the peripheral common power supply wire 182 located in the peripheral region BB will not be too large when it passes through the corner position of the display panel 100, so that the current density of the peripheral common power supply wire 182 located in the peripheral region BB at the position where the width changes will not be too large, thereby solving the heating problem in local regions such as the corner position or the position where the width changes.

In some examples, as illustrated by FIG. 29 and FIG. 30, the mesh wires 181 located in the display region is connected to the peripheral common power supply wire 182 located in the peripheral region.

In some examples, as illustrated by FIG. 29 and FIG. 30, the peripheral common power supply wire 182 includes a third wire segment 182a with a third wire width and a fourth wire segment 182b with a fourth wire width, the third wire width and the fourth wire width are different, and the third wire segment 182a and the fourth wire segment 182b are directly connected. Because the wire width of the third wire segment 182a is different from the wire width of the fourth wire segment 182b, the wire width of the peripheral common power supply wire 182 changes at a connection position Q of the third wire segment 182a and the fourth wire segment 182b, and the current density at the connection position Q of the third wire segment 182a and the fourth wire segment 182b is higher than other positions, and local regions are prone to heat generation. By connecting the mesh wires 181 of the common power mesh layer 180 with the common power terminal of the bonding region CC, the current of the peripheral common power supply wire 182 located in the peripheral region BB can be dispersed, the current density of the peripheral common power supply wire 182 located in the peripheral region BB can be reduced, and the problem of local region heating can be solved. In some examples, as illustrated by FIG. 30, the fourth wire width of the fourth wire segment 182b is smaller than the third wire width of the third wire segment 182a. The decreased wire width results in the exceedingly high current density at the connection position Q of the fourth wire segment 182b and the third wire segment 182a, and local region is prone to heat generation. Connecting the mesh wires 181 of the common power supply mesh layer 180 to the common power terminal in the bonding region CC may disperse the current of the peripheral common power supply wire 182 in the peripheral region BB, solving the problem of local region heating.

In some examples, as illustrated by FIG. 29 and FIG. 30, an extending direction of the third wire segment 182a is different from an extending direction of the fourth wire segment 182b. For example, the connection position Q of the third wire segment 182a and the fourth wire segment 182b is located in a corner of the display panel. For example, as illustrated by FIG. 4, the first wire segment 111 and the second wire segment 112 are located in a region where two adjacent edges of the display panel 100 intersect with each other.

In some examples, as illustrated by FIG. 29 and FIG. 30, the third wire segment 182a includes an arc segment that is directly connected with the fourth wire segment 182b. For example, the arc segment is located in a corner of the display panel. For example, the arc segment is located in a region where two adjacent edges of the display panel intersect with each other.

In some examples, as illustrated by FIG. 29 and FIG. 30, a ratio of the third wire width to the fourth wire width is greater than or equal to 2. By reducing the fourth wire width of the fourth wire segment 182b, the border on a side where the fourth wire segment 182b is located can be narrowed, thereby realizing a narrow border. The embodiments of the present disclosure do not limit the ratio of the third wire width to the fourth wire width, which may be designed according to the requirements of the display panel. For example, the ratio may also be greater than or equal to 2.5, and the ratio may be greater than or equal to 3.

For example, the peripheral region BB includes the bonding region, and the fourth wire segment 182b is located at the side of the display region AA close to the bonding region. By reducing the fourth wire width of the fourth wire segment 182b, the border of the display region AA close to the bonding region can be narrowed. For example, as illustrated by FIG. 29 and FIG. 30, the border on the side where the fourth wire segment is located may be the lower border of the display panel.

In some examples, as illustrated by FIG. 31, the display panel further includes a light-emitting device layer EL located at a side of the common power supply mesh layer 180 away from the base substrate 130.

For example, as illustrated by FIG. 31, a planarization layer PLN may be further included between the common power supply mesh layer 180 and the light-emitting device layer EL.

In some examples, the display panel 100 further includes a plurality of pixels, each of the plurality of pixels includes an effective light-emitting region and a non-display region surrounding the effective light-emitting region. Orthographic projections of the mesh wires of the common power supply mesh layer 180 on the base substrate 130 is in an orthographic projection of the non-display region on the base substrate 130. The mesh wires of the common power supply mesh layer are arranged in the non-display region of the pixel to avoid affecting the effective light-emitting region.

FIG. 32 is another schematic sectional view of a display panel illustrated by FIG. 29, and FIG. 33 is a schematic plan view of a metal mesh structure of FIG. 32. As illustrated by FIG. 29, FIG. 30, FIG. 32, and FIG. 33, the display panel 100 further includes a common power supply wire 110 and a metal mesh structure 120, the common power supply wire 110 is located in the peripheral region BB, the metal mesh structure 120 is located in the peripheral region BB and is located at a side that the common power supply wire 110 close to the display region AA, the metal mesh structure 120 is connected to the common power supply wire 110, and a part of the wires of the metal mesh structure 120 extends to the display region AA. The pixel circuit driver layer 140 includes a plurality of conductive patterns arranged sequentially in a direction perpendicular to the base substrate 130, and the plurality of conductive patterns include a first conductive pattern, the common power supply wire and the metal mesh structure are located in a same conductive layer as the first conductive pattern. By connecting the mesh wire 181 of the common power supply mesh layer 180 to the common power supply terminal of the bonding region CC, the current of the common power supply wire 110 located in the peripheral region BB can be dispersed, the current density of the common power supply wire 110 in the peripheral region BB can be reduced, solving the problem of local region heating.

In some examples, as illustrated by FIG. 33, the common power supply wire 110 includes a wire segment 111 and a wire segment 112, the wire width of the wire segment 111 is different from the wire width of the wire segment 112, the wire segment 111 and the wire segment 112 are directly connected, and the metal mesh structure 120 is located at the connection position P of the wire segment 111 and the wire segment 112. The wire width of the common power supply wire 110 changes due to the difference in the wire widths of the wire segment 111 and the wire segment 112, and the current density at the connection position P of the wire segment 111 and wire segment 112 is greater than the current density at the other positions. By connecting the mesh wire 181 of the common power supply mesh layer 180 to the common power supply terminal of the bonding region CC may further disperse the current of the common power supply wire 110 in the peripheral region BB and reduce the current density of the common power supply wire 110 in the peripheral region BB, solving the problem of local region heating.

In some examples, as illustrated by FIG. 30, FIG. 32, and FIG. 33, the metal mesh structure 120 has approximately a same mesh pattern as the common power supply mesh layer 180.

For example, in the direction perpendicular to the base substrate 130, the wire segment 111 corresponds to the third wire segment 182a, the wire segment 112 corresponds to the fourth wire segment 182b, and the connection position P corresponds to the connection position Q. For example, in the direction perpendicular to the base substrate 130, the wire segment 111 overlaps the third wire segment 182a, the wire segment 112 overlaps with the fourth wire segment 182b, and the connection position P overlaps the connection position Q.

In some examples, as illustrated by FIG. 33, the metal mesh structure 120 may be the metal mesh structure 120 in any embodiment described above, which will not be described again here.

The embodiments of the present disclosure provide a display device. FIG. 34 is a schematic diagram of a display device according to an embodiment of the present disclosure. As illustrated by FIG. 34, the display device 200 includes any display panel 100 described above.

For example, the display device 200 may be a display device 200 with a display function such as a TV, a computer monitor, a laptop computer, a tablet computer, a smart phone, a navigator, an electronic picture frame, or a car display.

The following points required to be explained:
(1) the drawings of the embodiments of the present disclosure only relate to the structures related to the embodiments of the present disclosure, and other structures can refer to the general design.
(2) without conflict, the embodiments of the present disclosure and the features in the embodiments may be combined with each other.

The above is only the specific embodiment of the present disclosure, but the protection scope of the present disclosure is not limited thereto. Any person familiar with the technical field can easily think of changes or substitutions within the technical scope disclosed in the present disclosure, and they should be included in the protection scope of the present disclosure. Therefore, the scope of protection of the present disclosure should be based on the scope of protection of the claims.

1. A display panel, comprising a display region and a peripheral region around the display region, wherein the display panel comprises a common power supply wire in the peripheral region and a metal mesh structure in the peripheral region, the metal mesh structure is located at a side of the common power supply wire close to the display region, the metal mesh structure is connected to the common power supply wire, and a part of wires of the metal mesh structure extends to the display region,
the common power supply wire comprises a first wire segment with a first wire width and a second wire segment with a second wire width, the first wire width is different from the second wire width, and the first wire segment is directly connected to the second wire segment,
the metal mesh structure comprises a functional mesh portion and a main mesh portion, the functional mesh portion is closer to a connection position of the first wire segment and the second wire segment than the main mesh portion, and
a resistance per unit area of the functional mesh portion is smaller than a resistance per unit area of the main mesh portion.

2. The display panel according to claim 1, wherein an extending direction of the first wire segment is different from an extending direction of the second wire segment.

3. The display panel according to claim 1, wherein the first wire segment comprises an arc segment, the arc segment is directly connected to the second wire segment.

4. The display panel according to claim 1, wherein the main mesh portion comprises a first mesh portion and a second mesh portion, the first mesh portion and the second mesh portion are located at two sides of the functional mesh portion, the first mesh portion is connected with the first wire segment, the second mesh portion is connected with the second wire segment, and the functional mesh portion is connected with both the first wire segment and the second wire segment.

5. (canceled)

6. (canceled)

7. (canceled)

8. The display panel according to claim 1, wherein the functional mesh portion and the main mesh portion are arranged in a same layer,
a number of mesh wires per unit area of the functional mesh portion is greater than a number of mesh wires per unit area of the main mesh portion, and/or
a wire width of each of the mesh wires of the functional mesh portion is greater than a wire width of each of the mesh wires of the main mesh portion, and/or
a number of mesh wires per unit area of the functional mesh portion decreases in a direction of the functional mesh portion towards the main mesh portion.

9. (canceled)

10. (canceled)

11. The display panel according to claim 1, wherein the functional mesh portion and the main mesh portion are arranged in a same layer, the main mesh portion comprises a first mesh pattern, the functional mesh portion comprises a second mesh pattern, the second mesh pattern comprises the first mesh pattern and a plurality of straight wire segments, and the plurality of straight wire segments extend from a side of the functional mesh portion close to the display region to the common power supply wire in a divergent manner.

12. The display panel according to claim 1, wherein the functional mesh portion comprises a first mesh layer and a second mesh layer electrically connected to each other, the first mesh layer and the main mesh portion are arranged in a same layer, and the first mesh layer and the second mesh layer are arranged in different layers.

13. (canceled)

14. The display panel according to claim 12, further comprising:
a base substrate and a pixel circuit driver layer formed on the base substrate,
wherein the pixel circuit driver layer comprises a plurality of conductive patterns arranged sequentially in a direction perpendicular to the base substrate, and the plurality of conductive patterns comprise a first conductive pattern and a second conductive pattern,
the first mesh layer and the main mesh portion are located in a same conductive layer as the first conductive pattern, and the second mesh layer is located in a same conductive layer as the second conductive pattern,
the first mesh layer is located at a side of the second mesh layer away from the base substrate,
in the direction perpendicular to the base substrate, an orthographic projection of each of mesh wires of the first mesh layer on the base substrate falls into an orthographic projection of each of mesh wires of the second mesh layer on the base substrate.

15. (canceled)

16. The display panel according to claim 12, further comprising:
a base substrate, a pixel circuit driver layer formed on the base substrate and a shielding metal layer located between the base substrate and the pixel circuit driver layer,
wherein the pixel circuit driver layer comprises a plurality of conductive patterns arranged sequentially in a direction perpendicular to the base substrate, and the plurality of conductive patterns comprise a first conductive pattern,
the first mesh layer and the main mesh portion are located in a same conductive layer as the first conductive pattern, and the second mesh layer is located in a same conductive layer as the shielding metal layer.

17. (canceled)

18. The display panel according to claim 12, further comprising:
a base substrate, a pixel circuit driver layer formed on the base substrate, and a first electrode layer formed on a side of the pixel circuit driver layer away from the base substrate,
wherein the pixel circuit driver layer comprises a plurality of conductive patterns arranged sequentially in a direction perpendicular to the base substrate, and the plurality of conductive patterns comprise a first conductive pattern,
the first mesh layer and the main mesh portion are located in a same conductive layer as the first conductive pattern, and the second mesh layer is located in a same conductive layer as the first electrode layer.

19. The display panel according to claim 1, further comprising:
a base substrate, wherein the metal mesh structure is located on the base substrate;
a plurality of insulation layers, located at a side of the metal mesh structure away from the base substrate,
wherein, along a direction perpendicular to the base substrate, a thickness of a region of the plurality of insulating layers overlapping with the functional mesh portion is smaller than a thickness of other region of the plurality of insulating layers.

20. The display panel according to claim 1, further comprising:
first transfer wires, extending in a first direction;
second transfer wires, extending in a second direction and arranged in a different layer as the first transfer wires;
first dummy wires, extending in the first direction;
second dummy wires, extending in the second direction and arranged in a different layer as the first dummy wires;
data wires, extending in the second direction,
wherein an end of each of the first transfer wires is connected with one of the data wires through one of first via holes, another end of each of the first transfer wires is connected with one of the second transfer wires through one of second via holes, the first via holes and the second via holes form a first transfer region, the peripheral region comprises a bonding region, and the first transfer region is located at a side of the display region close to the bonding region,
the display panel further comprises a light-emitting component, the first dummy wires and the second dummy wires are connected with a cathode of the light-emitting component and are configured to transmit a power supply voltage, the first dummy wires and the second dummy wires are connected through third via holes, and the third via holes form a plurality of second transfer regions.

21. The display panel according to claim 20, wherein the part of the wires of the metal mesh structure extending into the display region comprises a part of the first dummy wires, or the part of the wires of the metal mesh structure extending into the display region comprises a part of the second dummy wires,
the display panel further comprises:
a base substrate and a pixel circuit driver layer formed on the base substrate,
wherein the pixel circuit driver layer comprises a plurality of conductive patterns arranged sequentially in a direction perpendicular to the base substrate, and the plurality of conductive patterns comprise a first conductive pattern and a second conductive pattern,
the first transfer wires and the first dummy wires are located in a same conductive layer as the first conductive pattern, and the second transfer wires and the second dummy wires are located in a same conductive layer as the second conductive pattern.

22. (canceled)

23. The display panel according to claim 1, further comprising:
third transfer wires, extending in the first direction;
fourth transfer wires, extending in the second direction and arranged in a different layer as the third transfer wires;
third dummy wire, extending in the first direction;
fourth dummy wire, extending in the second direction and arranged in a different layer as the third dummy wires;
data wires, extending in the second direction,
wherein an end of each of the third transfer wires is connected with one of the data wires through one of fourth via holes, another end of each of the third transfer wires is connected with one of the fourth transfer wires through one of fifth via holes, the fourth via holes and the fifth via holes form a plurality of third transfer regions, the plurality of third transfer regions are spaced with each other in the first direction, the display panel comprises a display region and a peripheral region surrounding the display region, the peripheral region comprises a bonding region, and the plurality of third transfer regions are located at a side of the display region close to the bonding region,
the display panel further comprises a light-emitting component, the third dummy wires and the fourth dummy wires are connected with a cathode of the light-emitting component and are configured to transmit a power supply voltage, the third dummy wires and the fourth dummy wires are connected through sixth via holes, and the sixth via holes form a plurality of fourth transfer regions,
along the first direction, at least one of the plurality of fourth transfer regions is located among the plurality of third transfer regions.

24. The display panel according to claim 23, further comprising:
a lead wire, located between the display region and the bonding region,
wherein the bonding region comprises a common power supply terminal, the common power supply terminal is configured to transmit a common power supply signal, and an end of the lead wire is connected to the common power supply terminal,
the plurality of fourth transfer regions comprise a first sub-region, and along the first direction, the first sub-region is located among the plurality of third transfer regions, and a part of the fourth dummy wires in the first sub-region is connected with another end of the lead wire,
the display panel further comprises:
a base substrate;
a pixel circuit driver layer, located on the base substrate; and
a common power supply mesh layer, located at a side of the pixel circuit driver layer away from the base substrate,
wherein the pixel circuit driver layer comprises a plurality of conductive patterns arranged sequentially in a direction perpendicular to the base substrate, and the metal mesh structure and the common power supply wire are located in a same conductive layer as the plurality of conductive patterns,
the common power supply mesh layer comprises mesh wires located in the display region and a peripheral common power supply wire located in the peripheral region,
the peripheral region comprises a bonding region, the display panel further comprises a lead wire, the lead wire is located between the display region and the bonding region, the bonding region comprises a common power supply terminal, the common power supply terminal is configured to transmit a common power supply signal, an end of the lead wire is connected to the common power supply terminal and another end of the lead wire is connected to the mesh wires of the common power mesh layer.

25. (canceled)

26. (canceled)

27. (canceled)

28. A display panel comprising:
third transfer wires, extending in a first direction;
fourth transfer wire, extending in a second direction and arranged in a different layer as the third transfer wires;
third dummy wires, extending in the first direction;
fourth dummy wire, extending in the second direction and arranged in a different layer as the third dummy wires;
data wires, extending in the second direction,
wherein an end of each of the third transfer wires is connected with one of the data wires through one of fourth via holes, another end of each of the third transfer wires is connected with one of the fourth transfer wires through one of fifth via holes, the fourth via holes and the fifth via holes form a plurality of third transfer regions, the plurality of third transfer regions are spaced with each other in the first direction, the display panel comprises a display region and a peripheral region surrounding the display region, the peripheral region comprises a bonding region, and the plurality of third transfer regions are located at a side of the display region close to the bonding region,
the display panel further comprises a light-emitting component, the third dummy wires and the fourth dummy wires are connected with a cathode of the light-emitting component and are configured to transmit a power supply voltage, the third dummy wires and the fourth dummy wires are connected through sixth via holes, and the sixth via holes form a plurality of fourth transfer regions,
along the first direction, at least one of the plurality of fourth transfer region is located among the plurality of third transfer regions.

29. The display panel according to claim 28, further comprising:
a lead wire, located between the display region and the bonding region,
wherein the bonding region comprises a common power supply terminal, the common power supply terminal is configured to transmit a common power supply signal, and an end of the lead wire is connected to the common power supply terminal,
the plurality of fourth transfer regions comprise a first sub-region, and along the first direction, the first sub-region is located among the plurality of third transfer regions, and a part of the fourth dummy wires of the first sub-region is connected with another end of the lead wire,
the third transfer wires are arranged in a same layer as the third dummy wires, and/or the fourth transfer wires are arranged in a same layer as the fourth dummy wires.

30. (canceled)

31. (canceled)

32. (canceled)

33. A display panel comprising:
a base substrate;
a pixel circuit driver layer, located on the base substrate; and
a common power supply mesh layer located at a side of the pixel circuit driver layer away from the base substrate,
wherein the display panel comprises a display region and a peripheral region surrounding the display region, and the common power supply mesh layer comprises mesh wires located in the display region and a peripheral common power supply wire located in the peripheral region,
the peripheral region comprises a bonding region, the display panel further comprises a lead wire located between the display region and the bonding region, the bonding region comprises a common power supply terminal, the common power supply terminal is configured to transmit a common power supply signal, an end of the lead wire is connected to the common power supply terminal and another end of the lead wire is connected to the mesh wires of the common power mesh layer.

34. The display panel according to claim 33, wherein the peripheral common power supply wire comprises a third wire segment with a third wire width and a fourth wire segment with a fourth wire width, the third wire width is different from the fourth wire width, and the third wire segment is directly connected to the fourth wire segment.

35. (canceled)

36. (canceled)

37. The display panel according to claim 33, further comprising:
a common power supply wire, located in the peripheral region; and
a metal mesh structure, located in the peripheral region and on a side of the common power supply wire close to the display region,
wherein the metal mesh structure is connected with the common power supply wire, and a part of wires of the metal mesh structure extends to the display region,
the pixel circuit driver layer comprises a plurality of conductive patterns arranged sequentially in a direction perpendicular to the base substrate, and the plurality of conductive patterns comprise a first conductive pattern, the common power supply wire and the metal mesh structure are located in a same conductive layer as the first conductive pattern.

38. (canceled)
